(19) United States
(12) Patent Application Publication
(10) Pub. No.: US 2024/0170382 A1
(43) Pub. Date: May 23, 2024

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventor: Juhyeon Oh, Suwon-si (KR)

(21) Appl. No.: 18/504,195

(22) Filed: Nov. 8, 2023

(30) Foreign Application Priority Data
Nov. 23, 2022 (KR) 10-2022-0158146

(51) Int. Cl. H01L 23/498; H01L 23/00; H01L 23/31; H01L 23/522; H01L 25/065

(52) U.S. Cl. CPC H01L 23/49822; H01L 23/3128; H01L 23/49816; H01L 23/5226; H01L 24/08; H01L 24/16; H01L 24/32; H01L 24/48; H01L 24/73; H01L 25/0657; H01L 2224/081; H01L 2224/16245; H01L 2224/32145; H01L 2224/32225; H01L 2224/32245; H01L 2224/48145; H01L 2224/48227; H01L 2224/73204; H01L 2224/73215; H01L 2924/1431; H01L 2924/1436; H01L 2924/1437; H01L 2924/1438; H01L 2924/1441; H01L 2924/181

(57) ABSTRACT

A semiconductor package includes a lower redistribution wiring layer including first redistribution wiring, a semiconductor chip on the lower redistribution wiring layer and electrically connected to the first redistribution wirings, a sealing member on the semiconductor chip on the lower redistribution wiring layer, a plurality of through vias penetrating the sealing member and electrically connected to the first redistribution wirings, an upper redistribution wiring layer on the sealing member and having second redistribution wirings electrically connected to the plurality of through vias. The second redistribution wirings includes buried wirings that are buried in a plurality of recesses formed in an upper surface of the sealing member and electrically connected to the plurality of through vias, and upper redistribution wirings provided in at least one upper insulating layer on the sealing member and electrically connected to the buried wirings.

### CROSS-REFERENCE TO RELATED APPLICATION

This application claims priority under 35 U.S.C. § 119 to Korean Patent Application No. 10-2022-0158146, filed on Nov. 23, 2022, in the Korean Intellectual Property Office (KIPO), the contents of which are herein incorporated by reference in their entirety.

### FIELD

Example embodiments relate to a semiconductor package and a method of manufacturing the semiconductor package. More particularly, example embodiments relate to a fan out package and a method of manufacturing the same.

### BACKGROUND

When manufacturing a fan out package and after forming a sealing member covering a semiconductor chip on a lower redistribution wiring layer, an upper redistribution wiring layer may be formed on the sealing member. The upper redistribution wiring layer may include upper redistribution wirings electrically connected to mold through vias penetrating the sealing member. Since the upper redistribution wirings are stacked in a plurality of layers, a thickness of the upper redistribution wiring layer increases, which increases the total thickness of the package. Further, there the heat dissipation performance may deteriorate due to the sealing member having a relatively lower thermal conductivity.

### SUMMARY

Example embodiments provide a semiconductor package having reduced overall package thickness and improved heat dissipation characteristics.

Example embodiments provide a method of manufacturing the semiconductor package.

According to example embodiments, a semiconductor package includes a lower redistribution wiring layer including first redistribution wiring, a semiconductor chip on the lower redistribution wiring layer and electrically connected to the first redistribution wirings, a sealing member on the semiconductor chip on the lower redistribution wiring layer, a plurality of through vias penetrating the sealing member and electrically connected to the first redistribution wirings, an upper redistribution wiring layer on the sealing member and having second redistribution wirings electrically connected to the plurality of through vias. The second redistribution wirings includes buried wirings that are buried in a plurality of recesses formed in an upper surface of the sealing member and electrically connected to the plurality of through vias, and upper redistribution wirings provided in at least one upper insulating layer on the sealing member and electrically connected to the buried wirings.

In an example embodiment, at least one of the buried wirings partially contact the plurality of through vias. In an example embodiment, at least one of the buried wirings contact an upper sidewall of the plurality of through vias. In an example embodiment, an upper surface of the buried wirings and the upper surface of the sealing member are coplanar. In an example embodiment, a thickness of a buried wiring of the plurality of buried wirings is within a range of 3 μm to 20 μm, including endpoints. In an example embodiment, the sealing member includes a first sealing portion covering an upper surface of the semiconductor chip and a second sealing portion covering an upper surface of the lower redistribution wiring layer around the semiconductor chip. In an example embodiment, the buried wirings are provided on an upper surface of the first sealing portion and an upper surface of the second sealing portion. In an example embodiment, the semiconductor chip is mounted on the lower redistribution wiring layer via conductive bumps. In an example embodiment, the sealing member exposes an upper surface of the semiconductor chip. In an example embodiment, the semiconductor package includes a second package disposed on the upper redistribution wiring layer, wherein the second package includes a package substrate and at least one second semiconductor chip on the package substrate.

According to example embodiments, a semiconductor package includes a lower redistribution wiring layer including first redistribution wirings, a semiconductor chip on the lower redistribution wiring layer, wherein the semiconductor chip includes chip pads formed on a first surface of the semiconductor chip, and wherein the first surface of the semiconductor chip faces the lower redistribution wiring layer, a sealing member on the semiconductor chip on the lower redistribution wiring layer, a plurality of through vias penetrating the sealing member and electrically connected to the first redistribution wirings, and an upper redistribution wiring layer on the sealing member. The upper redistribution wiring layer includes buried wirings formed in recesses of an upper surface of the sealing member and electrically connected to the plurality of through vias, at least one upper insulating layer on the upper surface of the sealing member, and upper redistribution wirings provided in the at least one upper insulating layer and electrically connected to the buried wirings.

According to example embodiments, a semiconductor package includes a lower redistribution wiring layer including first redistribution wirings, a semiconductor chip on the lower redistribution wiring layer, wherein the semiconductor chip includes chip pads formed on a first surface of the semiconductor chip, and wherein the first surface of the semiconductor chip faces the lower redistribution wiring layer, a sealing member on an outer surface of the semiconductor chip on the lower redistribution wiring layer and exposing a second surface of the semiconductor chip opposite to the first surface, a plurality of through vias penetrating the sealing member and electrically connected to the first redistribution wirings, and an upper redistribution wiring layer on the sealing member and having second redistribution wirings electrically connected to the plurality of through vias. The second redistribution wirings includes buried wirings that are buried in a plurality of recesses formed in an upper surface of the sealing member and electrically connected to the plurality of through vias, and an upper redistribution wiring provided in at least one upper insulating layer that is on the sealing member and electrically connected to the buried wirings.

According to example embodiments, in a method of manufacturing a semiconductor package, a lower redistribution wiring layer including first redistribution wirings is formed. A semiconductor chip is mounted on the lower redistribution wiring layer, the semiconductor chip having chip pads electrically connected to the first redistribution wirings. A sealing member is formed on the lower redistribution wiring layer to cover the semiconductor chip. A plurality of through vias is formed to penetrate the sealing member and to be electrically connected to the first redistribution wirings. A plurality of recesses is formed in an upper surface of the sealing member to at least partially expose the through vias. A conductive material may be buried in the recesses to form a plurality of buried wirings. An upper redistribution layer having second redistribution wires is formed on the upper surface of the sealing member, the second redistribution wirings being electrically connected to the buried wirings.

According to example embodiments, an upper redistribution wiring layer of a semiconductor package may be disposed on a sealing member and may include second redistribution wirings electrically connected to a plurality of through vias that penetrate the sealing member. The second redistribution wirings may include buried wirings buried in recesses formed in an upper surface of the sealing member and electrically connected to the through vias, and upper redistribution wirings provided on at least one upper insulating layer stacked on the sealing member and electrically connected to the buried wirings.

The buried wiring may be buried in the upper surface of the sealing member to operate as an upper redistribution wiring of one layer. Accordingly, a thickness of the upper redistribution wiring layer may be reduced. Further, since the buried wirings have thermal conductivity higher than the sealing member including EMC, heat dissipation performances of the semiconductor package may be improved.

### BRIEF DESCRIPTION OF THE DRAWINGS

Example embodiments will be more clearly understood from the following detailed description taken in conjunction with the accompanying drawings. FIGS. 1 to 33 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is a plan view illustrating first upper redistribution wirings buried in an upper surface of a sealing member in FIG. 1.

FIG. 5 illustrates one or more steps of a method of manufacturing a semiconductor package in accordance with example embodiments.

FIG. 6 illustrates one or more steps of a method of manufacturing a semiconductor package in accordance with example embodiments.

FIG. 7 illustrates one or more steps of a method of manufacturing a semiconductor package in accordance with example embodiments.

FIG. 8 illustrates one or more steps of a method of manufacturing a semiconductor package in accordance with example embodiments.

FIG. 9 illustrates one or more steps of a method of manufacturing a semiconductor package in accordance with example embodiments.

FIG. 10 illustrates one or more steps of a method of manufacturing a semiconductor package in accordance with example embodiments.

FIG. 11 illustrates one or more steps of a method of manufacturing a semiconductor package in accordance with example embodiments.

FIG. 12 illustrates one or more steps of a method of manufacturing a semiconductor package in accordance with example embodiments.

FIG. 13 illustrates one or more steps of a method of manufacturing a semiconductor package in accordance with example embodiments.

FIG. 14 illustrates one or more steps of a method of manufacturing a semiconductor package in accordance with example embodiments.

FIG. 15 illustrates one or more steps of a method of manufacturing a semiconductor package in accordance with example embodiments.

FIG. 16 illustrates one or more steps of a method of manufacturing a semiconductor package in accordance with example embodiments.

FIG. 17 is a cross-sectional view illustrating a semiconductor package in accordance with example embodiments.

FIG. 18 is a cross-sectional view illustrating a semiconductor package in accordance with example embodiments.

FIG. 19 is a cross-sectional views illustrating one or more steps of a method of manufacturing a semiconductor package in accordance with example embodiments.

FIG. 20 is a cross-sectional views illustrating one or more steps of a method of manufacturing a semiconductor package in accordance with example embodiments.

FIG. 21 is a cross-sectional views illustrating one or more steps of a method of manufacturing a semiconductor package in accordance with example embodiments.

FIG. 22 is a cross-sectional views illustrating one or more steps of a method of manufacturing a semiconductor package in accordance with example embodiments.

FIG. 23 is a cross-sectional views illustrating one or more steps of a method of manufacturing a semiconductor package in accordance with example embodiments.

FIG. 24 is a cross-sectional views illustrating one or more steps of a method of manufacturing a semiconductor package in accordance with example embodiments.

FIG. 25 is a cross-sectional views illustrating one or more steps of a method of manufacturing a semiconductor package in accordance with example embodiments.

FIG. 26 is a cross-sectional views illustrating one or more steps of a method of manufacturing a semiconductor package in accordance with example embodiments.

FIG. 27 is a cross-sectional views illustrating one or more steps of a method of manufacturing a semiconductor package in accordance with example embodiments.

FIG. 28 is a cross-sectional views illustrating one or more steps of a method of manufacturing a semiconductor package in accordance with example embodiments.

FIG. 29 is a cross-sectional view illustrating a semiconductor package in accordance with example embodiments.

FIG. 30 is a cross-sectional views illustrating one or more steps of a method of manufacturing a semiconductor package in accordance with example embodiments.

FIG. 31 is a cross-sectional views illustrating one or more steps of a method of manufacturing a semiconductor package in accordance with example embodiments.

FIG. 32 is a cross-sectional views illustrating one or more steps of a method of manufacturing a semiconductor package in accordance with example embodiments.

FIG. 33 is a cross-sectional views illustrating one or more steps of a method of manufacturing a semiconductor package in accordance with example embodiments.

### DETAILED DESCRIPTION OF EXAMPLE EMBODIMENTS

Reference will now be made in detail to embodiments, examples of which are illustrated in the accompanying drawings, wherein like reference numerals refer to like elements throughout and the sizes of each of the elements may be exaggerated for clarity and conveniences of explanation.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. The term “and/or” includes any and all combinations of one or more of the associated listed items.

Spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below”, or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present inventive concept.

It will also be understood that when an element is referred to as being “on” or “connected to” another element, it can be directly on or connected to the other element, or intervening elements may be present. In contrast, when an element is referred to as being “directly on” or “directly connected to” another element, there are no intervening elements present. It will also be understood that the sizes and relative orientations of the illustrated elements are not shown to scale, and in some instances, they have been exaggerated for purposes of explanation.

Embodiments are described herein with reference to cross-sectional and/or perspective illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle may typically have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

As used herein, the phrase “at least one of A, B, and C” refers to a logical (A OR B OR C) using a non-exclusive logical OR, and should not be construed to mean “at least one of A, at least one of B and at least one of C.”

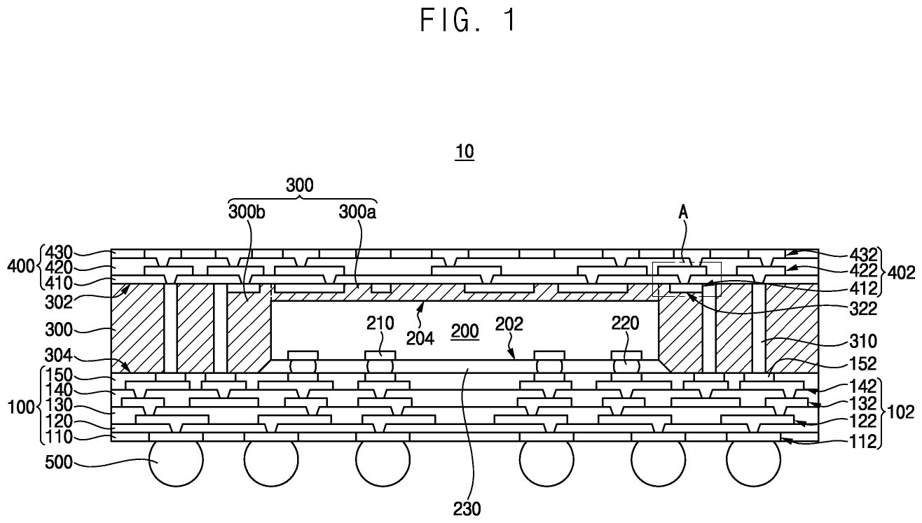

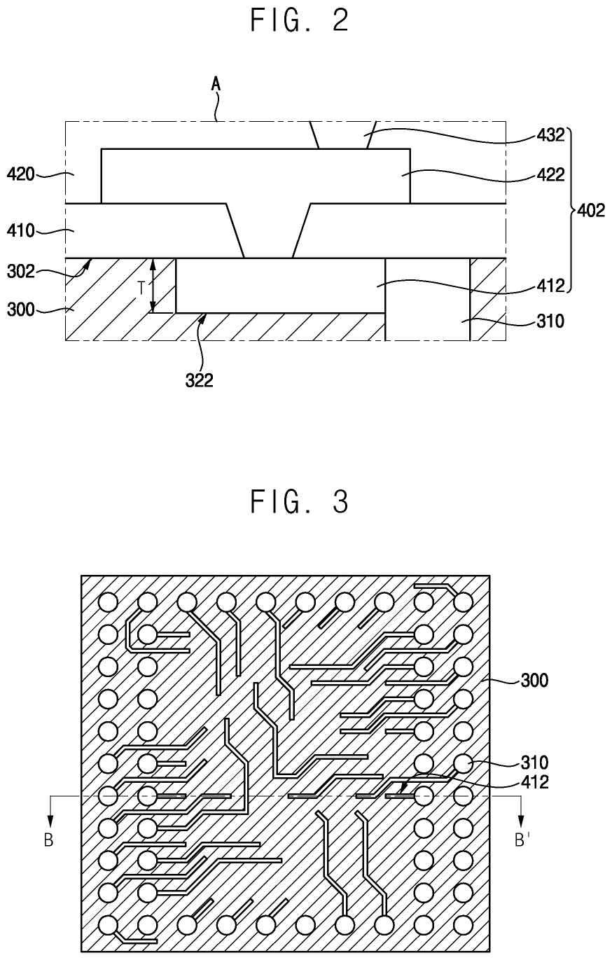

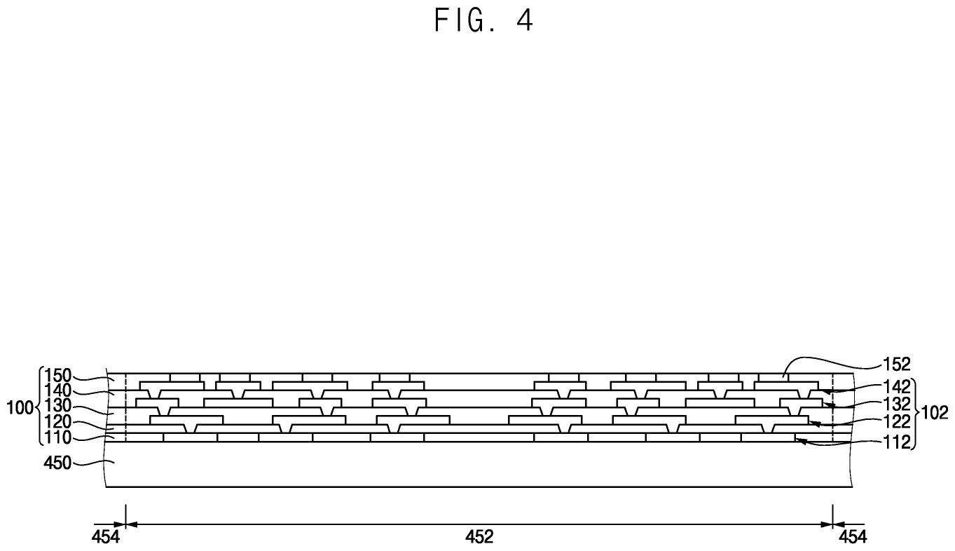

FIG. 1 is a cross-sectional view illustrating a semiconductor package in accordance with example embodiments. FIG. 2 is an enlarged cross-sectional view illustrating portion ‘A’ in FIG. 1. FIG. 3 is a plan view illustrating first upper redistribution wirings buried in an upper surface of a sealing member in FIG. 1. FIG. 1 is a cross-sectional view taken along the line B-B′ in FIG. 3.

Referring to FIGS. 1 to 3, a semiconductor package 10 may include a lower redistribution wiring layer 100, a semiconductor chip 200 disposed on the lower redistribution wiring layer 100, and a sealing member 300 on an upper surface of the lower redistribution wiring layer 100 and covering at least a portion of the semiconductor chip 200, and an upper redistribution wiring layer 400 disposed on an upper surface 302 of the sealing member 300. In addition, the semiconductor package 10 may further include external connection members 500 disposed on an outer surface of the lower redistribution wiring layer 100.

In example embodiments, the semiconductor package 10 may be a fan out package in which the lower redistribution wiring layer 100 extends to a lower surface of the sealing member 300 covering an outer surface of the semiconductor chip 200. The lower redistribution wiring layer 100 may be formed by a wafer level redistribution wiring process. Additionally, the semiconductor package 10 may be provided as a unit package on which a second package is stacked.

Additionally, the semiconductor package 10 may be provided as a System In Package (SIP). For example, one or more semiconductor chips may be disposed on the lower redistribution wiring layer 100. The semiconductor chips may include a logic chip including a logic circuit and/or a memory chip. The logic chip may be a controller that controls memory chips. The memory chip includes various types of memory circuits such as a dynamic random-access memory (DRAM), a static random-access memory (SRAM), flash, a phase change memory (PRAM), a resistive random-access memory (ReRAM), a ferroelectric random0access memory (FeRAM), or a magnetoresistive random-access memory (MRAM).

In example embodiments, the lower redistribution wiring layer 100 may have first redistribution wirings 102. The semiconductor chip 200 may be disposed on the lower redistribution wiring layer 100 to be electrically connected to the first redistribution wirings 102. The lower redistribution wiring layer 100 may be provided on a front surface 202 of the semiconductor chip 200 to operate as a front redistribution wiring layer. Accordingly, the lower redistribution wiring layer 100 may be a front redistribution wiring layer (FRDL) of the fan out package.

In particular, the lower redistribution wiring layer 100 may include a plurality of first, second, third, fourth and fifth lower insulating layers 110, 120, 130, 140 and 150 and the first redistribution wirings 102 provided in the first, second, third, fourth and fifth lower insulating layers. The first redistribution wirings 102 may include first, second, third and fourth lower redistribution wirings 112, 122, 132 and 142.

The first, second, third, fourth and fifth lower insulating layers 110, 120, 130, 140, 150 may include a polymer or a dielectric layer. For example, the first, second, third, fourth and fifth lower insulating layers 110, 120, 130, 140, 150 may include a photosensitive insulating layer, such as photo imageable dielectric (PID). The first, second, third, fourth and fifth lower insulating layers 110, 120, 130, 140, 150 may be formed by a vapor deposition process, a spin coating process, etc. The first redistribution wirings 112, 122, 132, 142 may include aluminum (Al), copper (Cu), tin (Sn), nickel (Ni), gold (Au), platinum (Pt), or an alloy thereof. The first redistribution wirings 112, 122, 132, 142 may be formed by a plating process, an electroless plating process, a vapor deposition process, etc.

In particular, the first lower redistribution wiring 112 may be provided in the first lower insulating layer 110. At least a portion of the first lower redistribution wiring 112 may operate as a bonding pad, or a bump pad may be formed on at least a portion of the first lower redistribution wiring 112. The second lower insulating layer 120 may be formed on the first lower insulating layer 110 and may have a first opening that exposes an upper surface of the first lower redistribution wiring 112.

The second lower redistribution wiring 122 may be formed on the second lower insulating layer 120 and may contact the first lower redistribution wiring 112 through the first opening formed in the second lower insulating layer 120. The third lower insulating layer 130 may be formed on the second lower insulating layer 120 and may have a second opening exposing the second lower redistribution wiring 122.

The third lower redistribution wiring 132 may be formed on the third lower insulating layer 130 and may contact the second lower redistribution wiring 122 through the second opening. The fourth lower insulating layer 140 may be formed on the third lower insulating layer 130 and may have a third opening exposing the third lower redistribution wiring 132.

The fourth lower redistribution wirings 142 may be formed on the fourth lower insulating layer 140 and may contact the third lower redistribution wiring 132 through the third opening.

A first bonding pad 152 may be disposed on the fourth lower redistribution wiring 142. A solder resist layer (as the fifth lower insulating layer 150) may be formed on the fourth lower insulating layer 140 and may expose at least a portion of the first bonding pad 152. The solder resist layer 150 may operate as a passivation layer.

The numbers and arrangements of the lower insulating layers and the lower redistribution wirings of the lower redistribution wiring layer are provided as examples, and it will be appreciated that the present disclosure is not limited thereto.

In example embodiments, the semiconductor chip 200 may have a plurality of chip pads 210 on a front surface 202, that is, an active surface thereof. The semiconductor chip 200 may be mounted on the lower redistribution wiring layer 100 such that the first surface on which the chip pads 210 are formed faces the lower redistribution wiring layer 100.

The semiconductor chip 200 may be mounted on the lower redistribution wiring layer 200 by a flip chip bonding method. The semiconductor chip 200 may be mounted on the lower redistribution wiring layer 100 via conductive bumps 220. The conductive bump 220 may be disposed between the bonding pad 152 on the fourth lower redistribution wiring 142 of the lower redistribution wiring layer 100 and the chip pad 210 of the semiconductor chip 200 to electrically connect the semiconductor chip 200 and the first redistribution wiring 102. For example, the conductive bump 220 may include a pillar bump formed on the chip pad 210 of the semiconductor chip 200 and a solder bump formed on the pillar bump. Alternatively, the conductive bump 220 may include a solder bump formed on the chip pad 210 of the semiconductor chip 200. An underfill member 230 may be disposed between the semiconductor chip 200 and the lower redistribution wiring layer 100.

Although only four chip pads 210 are illustrated in the figures, the structures and arrangements of the chip pads are provided as examples, and it will be understood that the present disclosure is not limited thereto. Additionally, although only one semiconductor chip is illustrated, it may not be limited thereto, and a plurality of semiconductor chips may be stacked on the lower redistribution wiring layer.

In example embodiments, the sealing member 300 may cover at least a portion of the semiconductor chip 200 on the upper surface of the lower redistribution wiring layer 100. The sealing member 300 may include a first molding portion 300a covering an upper surface 202 of the semiconductor chip 200 and a second sealing portion 300b covering the upper surface of the lower redistribution wiring layer 100 around the semiconductor chip 200.

For example, the sealing member 300 may include an epoxy mold compound (EMC). The sealing member 300 may be formed by a molding process, a screen-printing process, a lamination process, etc.

In example embodiments, a plurality of through vias 310 may extend in a vertical direction to penetrate the sealing member 300. The through via 310 may be formed on the bonding pad 152 on the fourth lower redistribution wiring 142.

The through via 310 may be provided to penetrate the sealing member 300 and may operate as an electrical connection path. The through via 310 may be a through mold via (TMV) formed to extend through the second sealing portion 300b of the sealing member 300. That is, the through vias 310 may be provided a fan out region outside an area where the semiconductor chip 200 is disposed to electrically connect the lower redistribution wiring layer 100 and the upper redistribution wiring layer 400.

In example embodiments, the upper redistribution wiring layer 400 may be disposed on the sealing member 300 and may include second redistribution wirings 402 electrically connected to the through vias 310 respectively. The second redistribution wirings 402 may include a buried wiring 412 buried in an upper surface 302 of the sealing member 300 and an upper redistribution wiring stacked in at least one layer on the buried wiring 412. The second redistribution wires 402 may be provided on the sealing member 300 to operate as backside redistribution wirings. Accordingly, the upper redistribution wiring layer 400 may be a backside redistribution wiring layer (BRDL) of the fan out package.

As illustrated in FIGS. 2 and 3, a plurality of recesses 322 may be provided in the upper surface 302 of the sealing member 300. The recess 322 may horizontally extend in the upper surface 302 of the sealing member 300 to at least partially expose an upper sidewall of the through via 310. The buried wirings 412 may be formed in the recesses 322 provided in the upper surface 302 of the sealing member 300. The buried wirings 412 may be provided in upper surfaces of the first sealing portion 300a and the second sealing portion 300b of the sealing member 300.

An upper surface of the buried wiring 412 and the upper surface 302 of the sealing member 300 may be coplanar with each other. A thickness T of the buried wiring 412 may be within a range of 3 μm to 20 μm, including endpoints. For example, the buried wiring may include copper (Cu), aluminum (Al), tin (Sn), nickel (Ni), gold (Au), platinum (Pt), or an alloy thereof.

The second redistribution wirings 402 may include the buried wirings 412 as first upper redistribution wirings, second upper redistribution wirings 422 and third upper redistribution wirings 432 stacked in three layers. In this case, the buried wiring 412 may correspond to a lowermost redistribution wiring among the upper redistribution wirings, and the third upper redistribution wiring 432 may correspond to an uppermost redistribution wiring among the upper redistribution wirings.

A first upper insulating layer 410 may be provided on the upper surface 302 of the sealing member 300 and may have openings that expose the upper surfaces of the buried wirings 412 and the through vias 310. The second upper redistribution wirings 422 may be formed on the first upper insulating layer 410 and at least portions of the second upper redistribution wirings 422 may directly contact the buried wirings 412 and the through vias 310 through the openings of the first upper insulating layer 410.

The second upper insulating layer 420 may be provided on the first upper insulating layer 410 and may have openings that expose the second upper redistribution wirings 422. The third upper redistribution wirings 432 may be formed on the second upper insulating layer 420 and at least portions of the third upper redistribution wirings 432 may directly contact the second upper redistribution wirings 422 through the openings of the second upper insulating layer 420.

Although not illustrated in the figures, second bonding pads may be provided on the third upper redistribution wirings 432 respectively. The third upper insulating layer 430 may be provided on the second upper insulating layer 420 and may expose at least portions of the second bonding pads. The third upper insulating layer 430 may operate as a passivation layer.

For example, the first, second and third upper insulating layers may include a polymer or a dielectric layer. The first, second and third upper insulating layers may include a photosensitive insulating material such as a photoresistive insulating dielectric (PID) or an insulating film, such as Ajinomoto build-up film (ABF). The second redistribution wirings may include copper (Cu), aluminum (Al), tin (Sn), nickel (Ni), gold (Au), platinum (Pt), or an alloy thereof. The second redistribution wirings 132 may include copper (Cu), aluminum (Al), tin (Sn), nickel (Ni), gold (Au), platinum (Pt), or an alloy thereof.

The numbers and arrangements of the upper insulating layers and the upper redistribution wirings of the upper redistribution wiring layer are provided as examples, and it will be understood that the present disclosure is not limited thereto.

In example embodiments, external connection members 500 may be disposed on bump pads on the first lower redistribution wirings 112 on the outer surface of the lower redistribution wiring layer 100. For example, the external connection member 500 may include a solder ball. The solder ball may have a diameter of 300 μm to 500 μm, including endpoints. The semiconductor package 10 may be mounted on a module substrate (not illustrated) via the solder balls to form a memory module.

As mentioned above, the semiconductor package 10 (as the fan out wafer level package) may include the lower redistribution wiring layer 100, the semiconductor chip 200 disposed on the lower redistribution wiring layer 100, the sealing member 300 covering at least a portion of the semiconductor chip 200 on the upper surface of the lower redistribution wiring layer 100, the plurality of through vias 310 penetrating the sealing member 300, and the upper redistribution wiring layer 400 disposed on the upper surface 302 of the sealing member 300.

The upper redistribution wiring layer 400 may include the second redistribution wirings 402 electrically connected to the plurality of through vias 310. The second redistribution wirings 402 may include the buried wirings 412 buried in the recesses 322 formed in the upper surface 302 of the sealing member 300 and electrically connected to the through vias 310, and the upper redistribution wirings 422 and 432 provided on the at least one upper insulating layer 410 and 420 stacked on the sealing member 300 and electrically connected to the buried wirings 412.

The buried wiring 412 may be buried in the upper surface 302 of the sealing member 300 to operate as the upper redistribution wiring of one layer. Accordingly, a thickness of the upper redistribution wiring layer 400 may be reduced. Further, since the buried wirings 412 have thermal conductivity higher than EMC, heat dissipation performances of the semiconductor package 10 may be improved.

Hereinafter, a method of manufacturing the semiconductor package of FIG. 1 will be described.

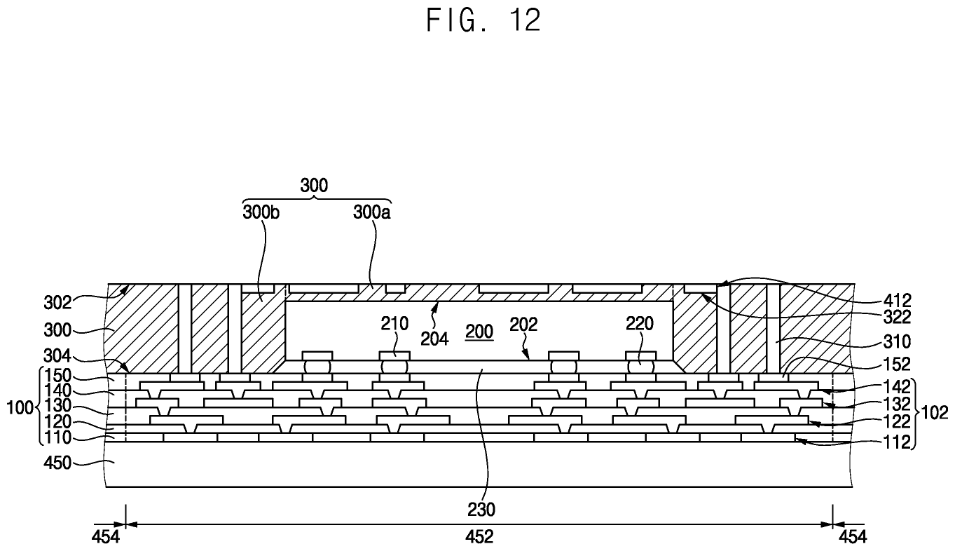

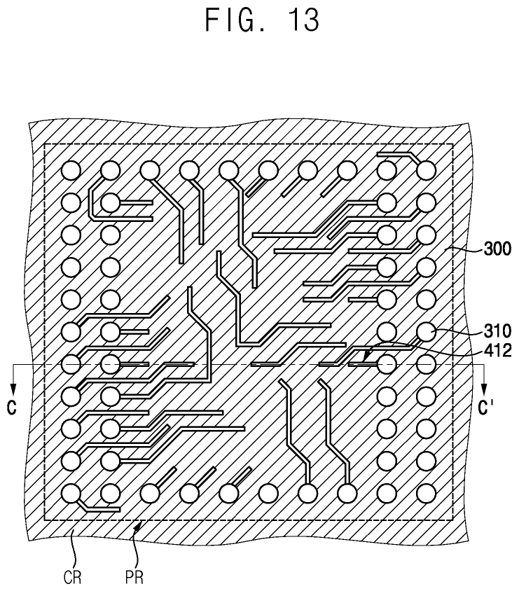

FIGS. 4 to 16 are views illustrating a method of manufacturing a semiconductor package in accordance with example embodiments. FIGS. 4 to 12 and 14 to 16 are cross-sectional views illustrating a method of manufacturing a semiconductor package in accordance with example embodiments. FIG. 13 is a plan view of FIG. 12. FIG. 12 is a cross-sectional view taken along the line C-C′ in FIG. 13.

Referring to FIG. 4, a lower redistribution wiring layer 100 having first redistribution wirings 102 may be formed on a carrier substrate 450.

In example embodiments, the carrier substrate 450 may include a wafer substrate as a base substrate for disposing a plurality of semiconductor chips on the lower redistribution wiring layer and forming a sealing member covering them. The carrier substrate 450 may have a shape corresponding to a wafer on which a semiconductor process is performed. For example, the carrier substrate 450 may include a silicon substrate, a glass substrate, a non-metal or metal plate, etc.

The carrier substrate 450 may include a package region 452 on which the semiconductor chip is mounted and a cutting region 454 surrounding the package region 452. As will be described later, the lower redistribution wiring layer 100 and the sealing member formed on the carrier substrate 450 may be cut along the cutting region 454 that divides the plurality of package regions to be individualized.

In example embodiments, a plating process may be performed on the carrier substrate 450 to form first lower redistribution wirings 312. Although it is not illustrated in the figures, after a barrier metal layer, a seed layer and a photoresist layer are sequentially formed on the carrier substrate 450, an exposure process may be performed on the photoresist layer to form a photoresist pattern having an opening that exposes a first lower redistribution region. Then, a plating process may be performed on the seed layer to form the first lower redistribution wirings 112. For example, the first lower redistribution may include copper (Cu), aluminum (Al), tin (Sn), nickel (Ni), gold (Au), platinum (Pt), or an alloy thereof.

Then, after a first lower insulating layer 110 is formed on the carrier substrate 450 to cover the first lower redistribution wirings 112, the first lower insulating layer 110 may be patterned to form openings that expose the first lower redistribution wirings 112.

For example, the first lower insulating layer 110 may include a polymer or a dielectric layer. The first lower insulating layer 110 may include a photosensitive insulating material, such as PID, or an insulating film, such as ABF. The first lower insulating layer may be formed by a spin coating process, a vapor deposition process, etc.

Then, after a second lower insulating layer 120 is formed on the first lower insulating layer 110, second lower redistribution wirings 122 may be formed on the second lower insulating layer 120.

For example, after the second lower insulating layer 120 is formed to cover the first lower redistribution wirings 112, the second lower insulating layer 120 may be patterned to form openings that expose the first lower redistribution wirings 112 respectively. After a seed layer is formed on portions of the first lower redistribution wirings 112 and in the opening, the seed layer may be patterned, and an electroplating process may be performed to form the second lower redistribution wirings 122. Accordingly, at least portions of the second lower redistribution wirings 122 may directly contact the first lower redistribution wirings 112 through the openings of the second lower insulating layer 120.

Similarly, after a third lower insulating layer 130 is formed on the second lower insulating layer 120, the third lower insulating layer 130 may be patterned to form openings that expose the second lower redistribution wirings 122. Then, third lower redistribution wirings 132 may be formed on the third lower insulating layer 130 to directly contact the second lower redistribution wirings 122 through the openings of the third lower insulating layer 130.

Then, after a fourth lower insulating layer 140 is formed on the third lower insulating layer 130, the fourth lower insulating layer 140 may be patterned to form openings that expose the third lower redistribution wirings 132. Then, fourth lower redistribution wirings 142 may be formed on the fourth lower insulating layer 140 to directly contact the third lower redistribution wirings 132 through the openings of the fourth lower insulating layer 140.

Then, first bonding pads 152 may be respectively formed on the fourth lower redistribution wirings 142. For example, the first bonding pad 152 may be formed by performing a plating process on a redistribution pad of the fourth lower redistribution wiring 142.

Then, a solder resist layer (as the fifth lower insulating layer 150) may be formed on the fourth lower insulating layer 140 to cover the fourth lower redistribution wirings 142 and exposes at least portions of the first bonding pads 152.

Thus, the lower redistribution wiring layer 100 having the first, second, third, fourth and fifth lower insulating layers 110, 120, 130, 140 and 150 may be formed. The lower redistribution wiring layer 100 may be a front redistribution wiring layer (FRDL) of a fan out package. The first bonding pads 152 may be exposed at an upper surface of the lower redistribution wiring layer 100.

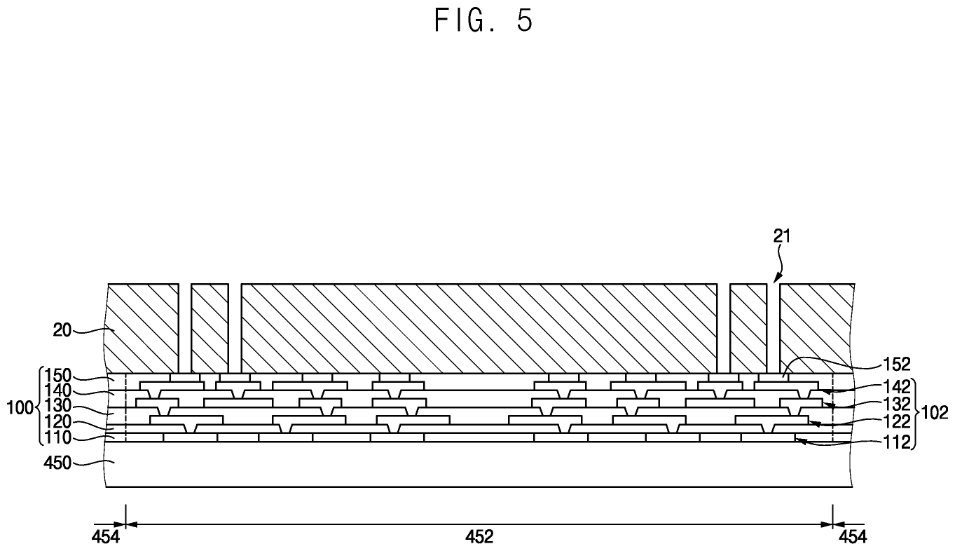

Referring to FIGS. 5 to 7, a plurality of through vias 310 as conductive structures may be formed on the upper surface of the lower redistribution wiring layer 100.

As illustrated in FIG. 5, a photoresist layer may be formed on the upper surface of the lower redistribution wiring layer 100 and an exposure process may be performed on the photoresist layer to form a photoresist pattern 20 having openings for forming a plurality of through vias on a fan out region of the lower redistribution wiring layer 100. The opening 21 may expose at least a portion of the first bonding pad 152 in the fan out region.

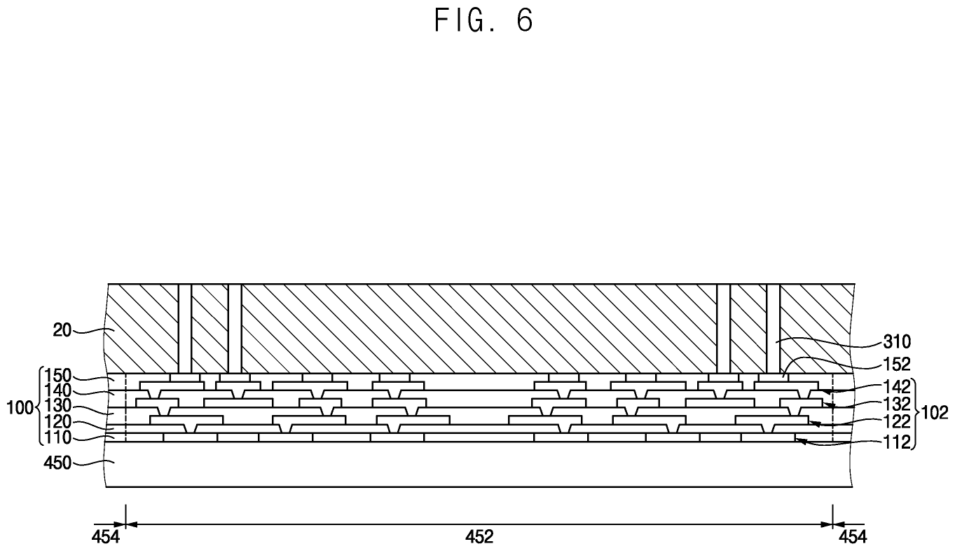

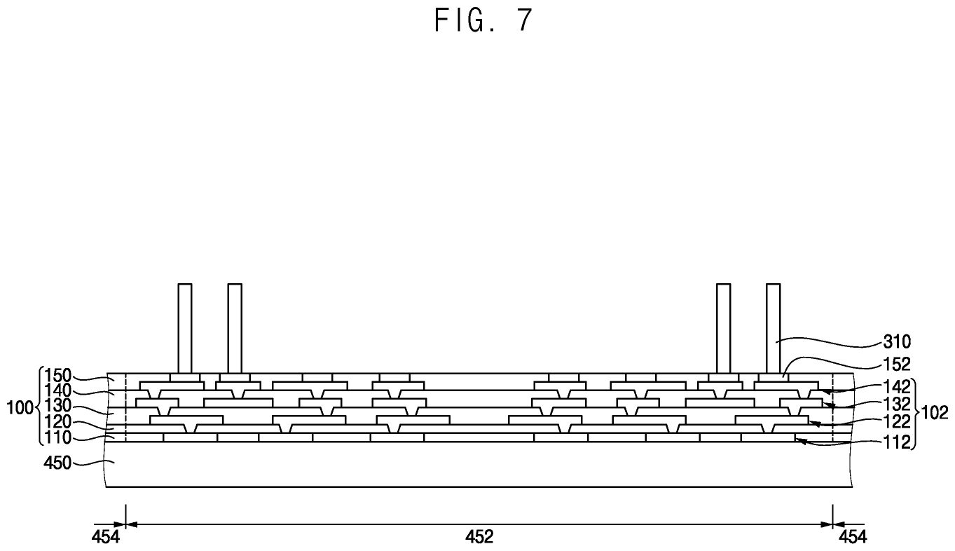

Then, as illustrated in FIGS. 6 and 7, an electroplating process may be performed to fill up the openings 21 of the photoresist pattern 20 with a conductive material to form through vias 310. Then, the photoresist pattern 20 may be removed by a strip process.

The through via 310 as a conductive connection structure may extend upward from the first bonding pad 152. The through vias 310 may be electrically connected to the first redistribution wirings 102. As will be described later, the through via 310 may be provided to penetrate a sealing member and operate as an electrical connection path. That is, the through vias 310 may be provided in the fan out region outside of an area where a semiconductor chip (die) is disposed and may be used for electrical connection.

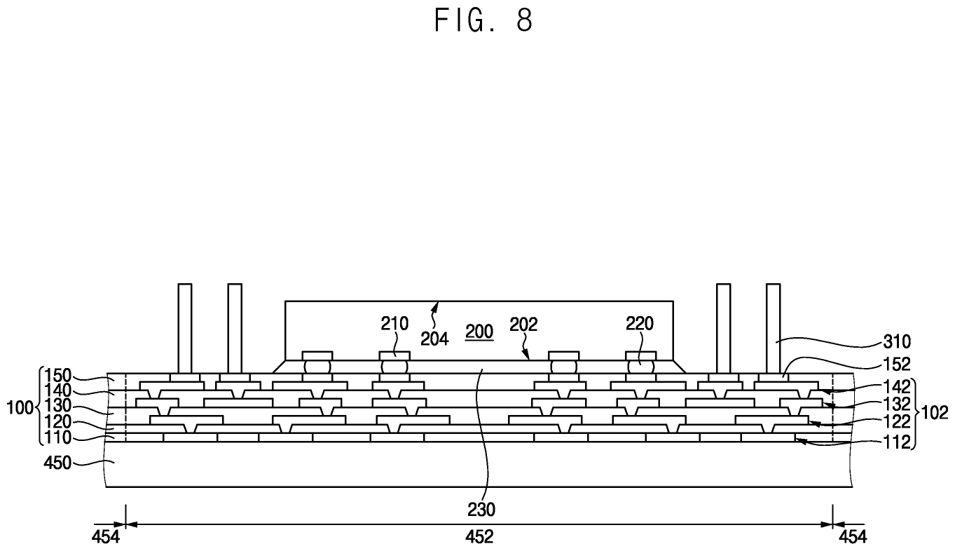

Referring to FIG. 8, at least one semiconductor chip 200 may be mounted on the upper surface of the lower redistribution wiring layer 100.

In example embodiments, the semiconductor chip 200 may be disposed on a fan in region of the lower redistribution wiring layer 100. The semiconductor chip 200 may be mounted on the upper surface of the lower redistribution wiring layer 100 by a flip chip bonding method. The semiconductor chip 200 may be disposed such that a front surface 202 on which chip pads 210 are formed, that is, an active surface, faces the lower redistribution wiring layer 100. The chip pads 210 of the semiconductor chip 200 may be electrically connected to the first redistribution wirings 102 of the lower redistribution wiring layer 100 by conductive bumps 220. For example, the conductive bumps 220 may include micro bumps.

An underfill member 230 may be underfilled between the semiconductor chip 200 and the lower redistribution wiring layer 100. The underfill member may include a material having relatively high fluidity to effectively fill a small space between the semiconductor chip and the lower redistribution wiring layer. For example, the underfill member may include an adhesive containing an epoxy material.

The semiconductor chip may be a logic chip including a logic circuit. The logic chip may be a controller that controls memory chips. The semiconductor chip may be a processor chip such as an application-specific integrated circuit (ASIC) or an application processor (AP) serving as a host such as a central processing unit (CPU), a graphics processing unit (GPU), or a system on chip (SOC).

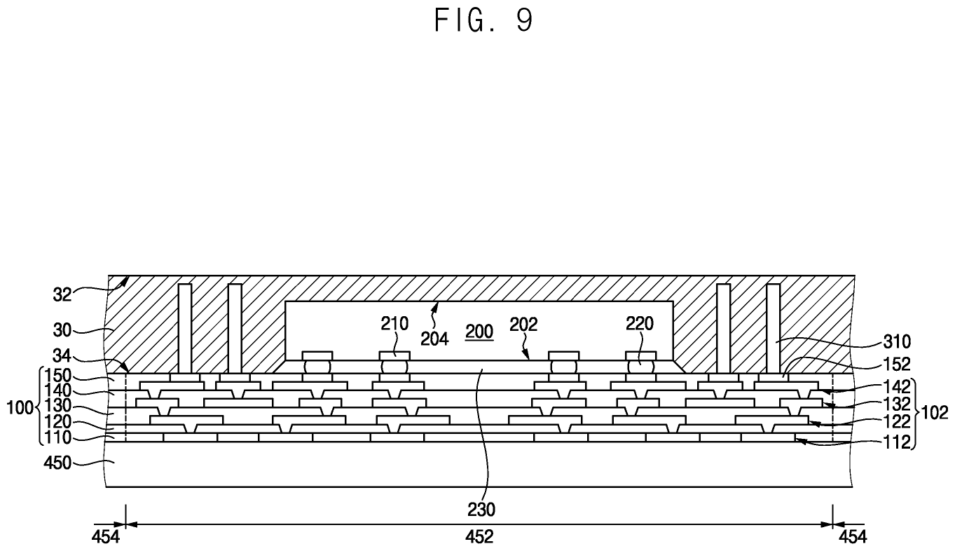

Referring to FIG. 9, a sealing material 30 may be formed on the upper surface of the lower redistribution wiring layer 100 to cover the semiconductor chip 200 and the plurality of through vias 310.

The sealing material 30 may be formed to cover an upper surface 202 of the semiconductor chip 200 and upper surfaces of the plurality of through vias 310. For example, the sealing material 30 may include an epoxy molding compound (EMC). The sealing material 30 may include UV resin, polyurethane resin, silicone resin, silica filler, etc.

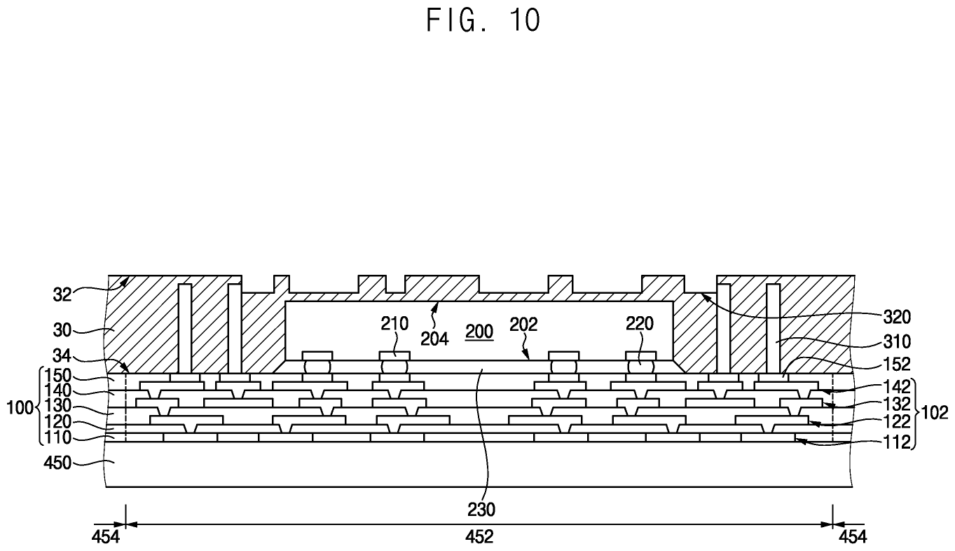

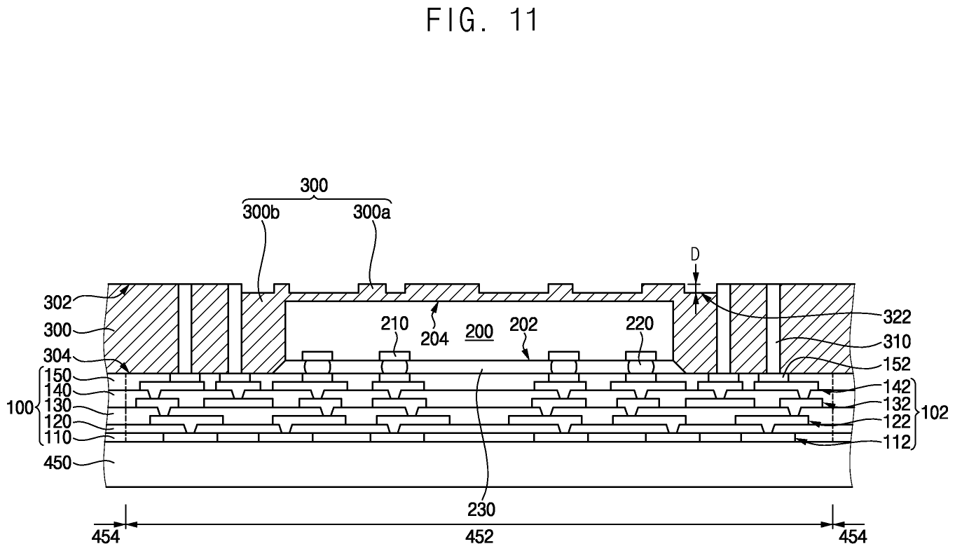

Referring to FIGS. 10 and 11, a plurality of recesses 322 may be formed in an upper surface of the sealing material 30 to at least partially expose the through vias 310.

As illustrated in FIG. 10, preliminary recesses 320 having a predetermined depth may be formed by performing laser processing on the upper surface 32 of the sealing material 30. The preliminary recesses 320 may be formed by patterning the upper surface 32 of the sealing material 30 using a laser processing process. The preliminary recess 320 may expose at least a portion of a sidewall of the through via 310.

As illustrated in FIG. 11, an upper portion of the sealing material 30 may be partially removed to form a sealing member 300 that exposes the upper surfaces of the plurality of through vias 310. The upper portion of the sealing material 30 may be partially removed by a grinding process.

As the upper portion of the sealing material 30 is removed, a plurality of recesses 322 may be formed in an upper surface 302 of the sealing member 300. The recess 322 may at least partially expose an upper sidewall of the through via 310. The recess 322 may have a depth D within a range of 3 μm to 20 μm, including endpoints, from the upper surface of the sealing member 300.

The sealing member 300 may include a first sealing portion 300a covering the upper surface 202 of the semiconductor chip 200 and a second sealing portion 300b covering the upper surface of the lower redistribution wiring layer 100 around the semiconductor chip 200.

Thus, the plurality of through vias 310 may be formed on the upper surface of the fan out region of the lower redistribution wiring layer 100 to penetrate the sealing member 300. The through via 310 may be a through mold via (TMV) formed through the second sealing portion 300b of the sealing member 300. In addition, the plurality of recesses 322 may be formed in upper surfaces of the first molding portion 300a and the second sealing portions 300b of the sealing member 300.

In FIGS. 10 and 11, after forming the preliminary recesses by laser processing, the upper portion of the sealing material may be grinded to expose the upper surfaces of the plurality of through vias and form the recesses, but the present disclosure may not be limited thereto. For example, after exposing the upper surfaces of the plurality of through vias by grinding the upper portion of the sealing material, the recesses may be formed in the upper surface of the sealing member through laser processing.

Referring to FIGS. 12 and 13, buried wirings 412 may be formed in the recesses 322 provided in the upper surface 302 of the sealing member 300.

In example embodiments, a plating process may be performed to fill the recesses 322 with a conductive material to form the buried wirings 412. For example, after a seed layer is formed in the recess 322, the seed layer may be patterned and an electroplating process may be performed to form the buried wirings 412. For example, the first lower redistribution wiring may include copper (Cu), aluminum (Al), tin (Sn), nickel (Ni), gold (Au), platinum (Pt), or an alloy thereof.

The buried wiring 412 may contact at least a portion of the upper sidewall of the through via 310. The buried wiring 412 may be electrically connected to the through via 310. An upper surface of the buried wiring 412 may be positioned on the same plane as the upper surface 302 of the sealing member 300.

The buried wiring 412 may be buried in the upper surface 302 of the sealing member 300 to operate as an upper redistribution wiring of a first layer. Accordingly, a thickness of an upper redistribution wiring layer to be described later may be reduced. Further, since the buried wirings 412 have higher thermal conductivity than EMC, heat dissipation performances of the semiconductor package may be improved.

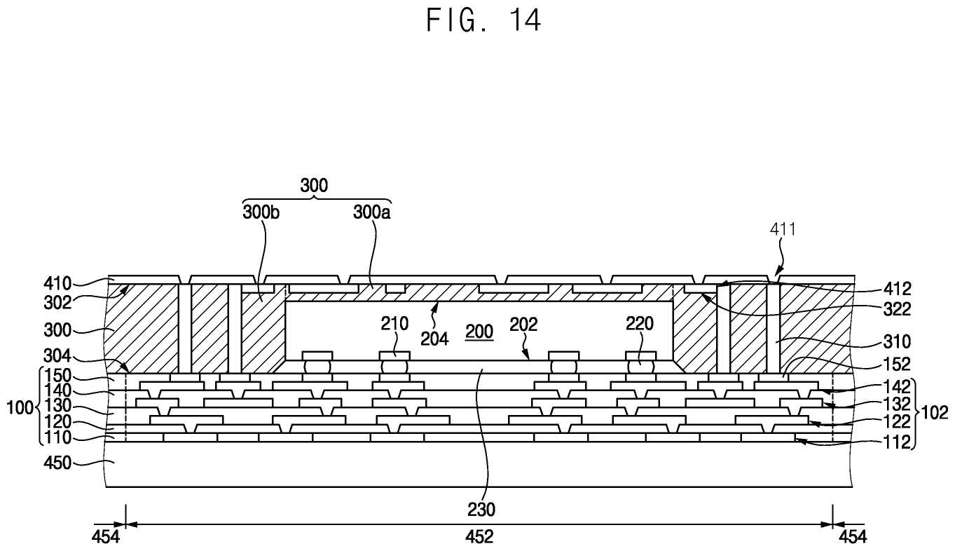

Referring to FIGS. 14 to 16, an upper redistribution wiring layer 400 having second redistribution wirings 402 electrically connected to the buried wirings 412 and the through vias 310 may be formed on the upper surface 302 of a sealing member 300.

As illustrated in FIG. 14, after a first upper insulating layer 410 is formed on the upper surface 302 of the sealing member 300, the first upper insulating layer 410 may be patterned to form openings 411 that expose the buried wirings 412 and the through vias 310 respectively. Some of the openings of the patterned first upper insulating layer 410 may expose the buried wirings 412 and other openings may expose the upper surfaces of the through vias 310.

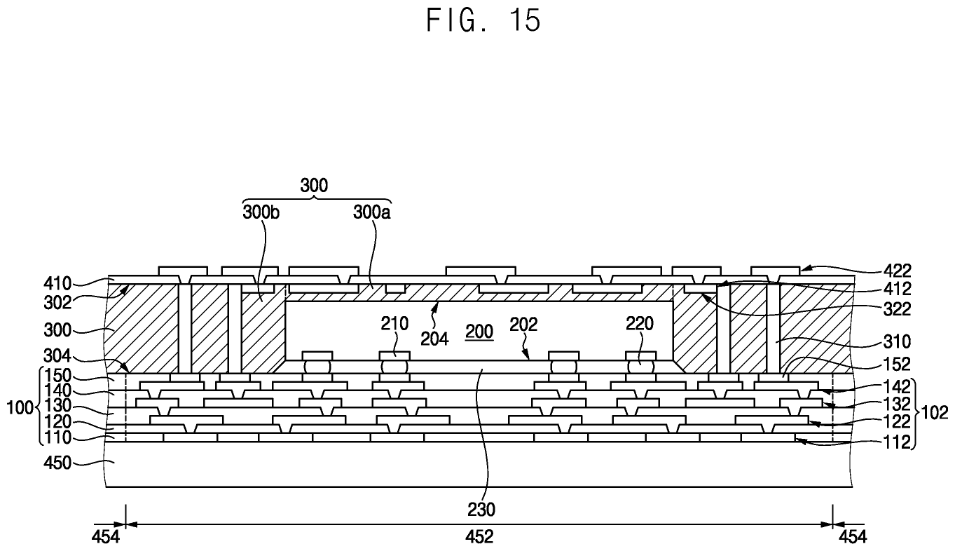

As illustrated in FIG. 15, after a seed layer is formed on portions of the buried wirings 412, portions of the through vias 310 and in the openings 411, the seed layer may be patterned and an electroplating process may be performed to form the second upper redistribution wirings 422. Accordingly, at least some of the second upper redistribution wirings 422 may directly contact the buried wiring 412 as the first upper redistribution wiring through the openings.

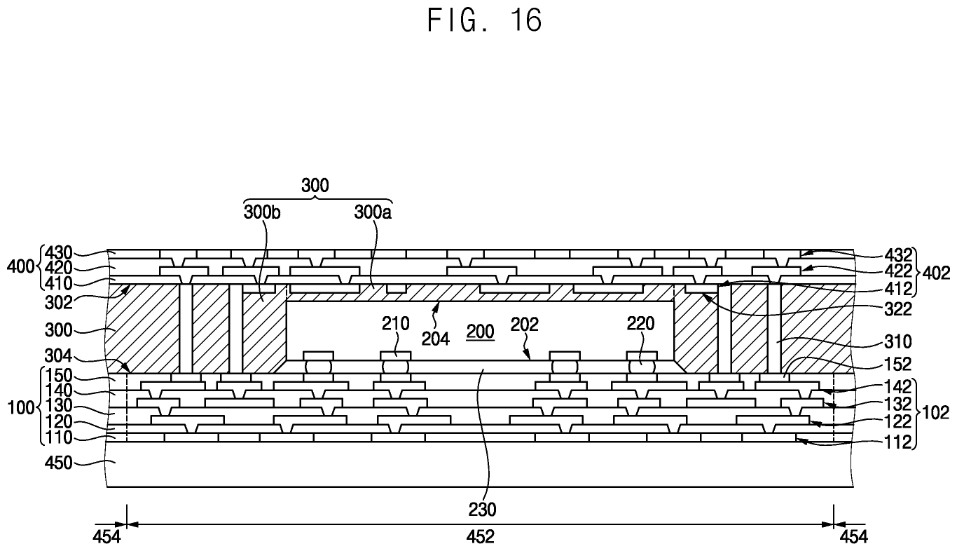

As illustrated in FIG. 16, after a second upper insulating layer 420 is formed on the first upper insulating layer 410, and the second upper insulating layer 420 may be patterned to form openings that expose the second upper redistribution wirings 422. Then, third upper redistribution wirings 432 may be formed on the second upper insulating layer 420 to directly contact the second upper redistribution wirings 422 through the openings of the second upper insulating layer 420.

Accordingly, the second redistribution wirings 402 may include the buried wirings 412, the second upper redistribution wiring 422 and the third upper redistribution wiring 432 stacked in three layers. In this case, the buried wiring 412 may correspond to a lowermost redistribution wiring among the upper redistribution wirings, and the third upper redistribution wiring 432 may correspond to an uppermost redistribution wiring among the upper redistribution wirings.

Then, second bonding pads (not illustrated) may be formed on the third upper redistribution wirings 432 as the uppermost redistribution wirings respectively, and a third upper insulating layer 430 may be formed on the second upper insulating layer 420 and may expose at least a portion of the second bonding pad on the third upper redistribution wiring 432. The third upper insulating layer 430 may operate as a passivation layer.

Then, external connection members 500 (see FIG. 1) may be formed on an outer surface of the lower redistribution wiring layer 100 to be electrically connected to the first redistribution wirings 102.

Then, a sawing process may be performed to individualize lower redistribution wiring layers 100 to complete the fan out wafer level package 10 of FIG. 1 including the sealing member 300, the lower redistribution wiring layer 100 formed on the lower surface 304 of the sealing member 300 and the upper redistribution wiring layer 400 formed on the upper surface 302 of the sealing member 300.

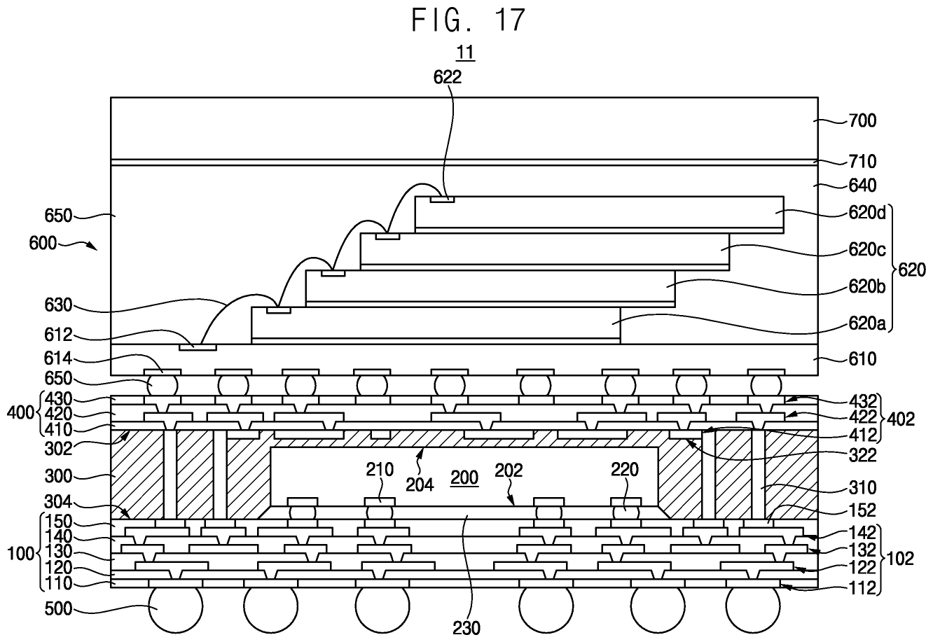

FIG. 17 is a cross-sectional view illustrating a semiconductor package in accordance with example embodiments. The semiconductor package may be substantially the same as the semiconductor package described with reference to FIG. 1 except for an additional second package. Thus, same reference numerals may be used to refer to the same or like elements and any further repetitive explanation concerning the above elements will be omitted.

Referring to FIG. 17, a semiconductor package 11 may include a first package and a second package 600 stacked on the first package. The semiconductor package 11 may further include a heat sink 700 stacked on the second package 600. The first package may include a lower redistribution wiring layer 100, a semiconductor chip 200, a sealing member 300 and an upper redistribution wiring layer 400. The first package may be substantially the same as or similar to the unit package described with reference to FIG. 1 (e.g., semiconductor package 10).

In example embodiments, the second package 600 may include a second package substrate 610, a plurality of second semiconductor chips 620 mounted on the second package substrate 610 and a sealing member 640 covering the second semiconductor chips 620a on the second package substrate 610.

The second package 600 may be stacked on the first package via conductive connection members 650. For example, the conductive connection members 650 may include solder balls, conductive bumps, etc. The conductive connection member 650 may be disposed between a bonding pad on a third upper redistribution wiring 432 of the upper redistribution wiring layer 400 and a second connection pad 614 of the second package substrate 610. Accordingly, the first package and the second package 600 may be electrically connected to each other by the conductive connection members 650.

A plurality of second semiconductor chips 620a, 620b, 620c and 620d may be sequentially stacked on the second package substrate 610 by adhesive members. Bonding wires 630 may connect second chip pads 622 of the second semiconductor chips 620 to first connection pads 612 of the second package substrate 610. The second semiconductor chips 620 may be electrically connected to the second package substrate 610 by the bonding wires 630.

Although the second package 600 includes four semiconductor chips mounted by a wire bonding method, it will be understood that the number of the semiconductor chips in the second package and the mounting method are not limited thereto.

In example embodiments, the heat sink 700 may be provided on the second package 600 to dissipate heat from the first and second packages to the outside. The heat sink 700 may be attached on the second package 600 by a thermal interface material (TIM) 710.

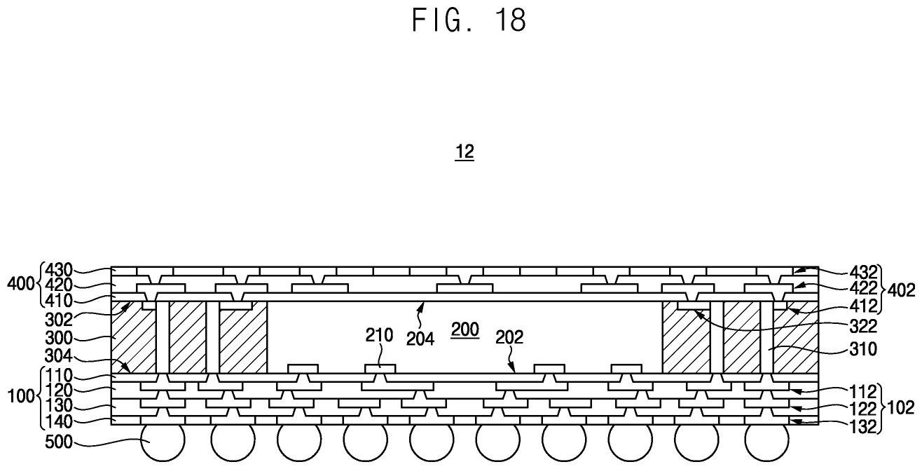

FIG. 18 is a cross-sectional view illustrating a semiconductor package in accordance with example embodiments. The semiconductor package may be substantially the same as the semiconductor package described with reference to FIG. 1 except for arrangements of semiconductor chips and a configuration of a sealing member. Thus, same reference numerals may be used to refer to the same or like elements and any further repetitive explanation concerning the above elements will be omitted.

Referring to FIG. 18, a semiconductor package 12 may include the lower redistribution wiring layer 100, the semiconductor chip 200 disposed on the lower redistribution wiring layer 100, the sealing member 300 covering at least one side surface of the semiconductor chip 200 on the lower redistribution wiring layer 100, and the upper redistribution wiring layer 400 disposed on the sealing member 300. In addition, the semiconductor package 12 may further include the external connection members 500 disposed on an outer surface of the lower redistribution wiring layer 100.

In example embodiments, the semiconductor chip 200 may have a plurality of chip pads 210 on the front surface 202, that is, an active surface. The semiconductor chip 200 may be accommodated in the sealing member 300 such that the front surface 202 on which the chip pads 210 are formed faces the lower redistribution wiring layer 100. The sealing member 300 may cover a side surface of the semiconductor chip 200. The front surface 202 of the semiconductor chip 200 may be exposed from the lower surface 304 of the sealing member 300, and the backside surface 202 opposite to the front surface 202 of the semiconductor chip 200 may be exposed from an upper surface 302 of the sealing member 300.

The plurality of through vias 310 may extend in a vertical direction to penetrate the sealing member 300. One end of the through via 310 may be exposed from the lower surface 304 of the sealing member 300 and the other end of the through via 310 may be exposed from the upper surface 302 of the sealing member 300.

In example embodiments, the lower redistribution wiring layer 100 may be disposed on the lower surface 304 of the sealing member 300 and the front surface 202 of the semiconductor chip 200. The lower redistribution wiring layer 100 may include the plurality of first redistribution wirings 102. The first redistribution wirings 102 may be electrically connected to the chip pads 210 of the semiconductor chip 200 and the through vias 310, respectively. The first redistribution wirings 102 may be provided on the front surface 202 of the semiconductor chip 200 and the lower surface 304 of the sealing member 300 to operate as front redistribution wirings. Accordingly, the lower redistribution wiring layer 100 may be a front redistribution wiring layer of a fan out package.

For example, the lower redistribution wiring layer 100 may include the first, second, third and fourth lower insulating layers 110, 120, 130 and 140 that are sequentially stacked. The first redistribution wirings 102 may include the first, second and third lower redistribution wirings 112, 122 and 132 provided in the first, second, third and fourth lower insulating layers 110, 120, 130 and 140, respectively.

In example embodiments, the upper redistribution wiring layer 400 may be disposed on the upper surface 302 of the sealing member 300 and the backside surface 202 of the semiconductor chip 200 and may include second redistribution wirings 402 electrically connected to the through vias 310. The second redistribution wirings 402 may include the buried wiring 412 buried in the upper surface 302 of the sealing member 300 and an upper redistribution wiring stacked in at least one layer on the buried wiring 412. The second redistribution wirings 402 may be provided on the sealing member 300 to operate as backside redistribution wirings. Accordingly, the upper redistribution wiring layer 400 may be a backside redistribution wiring layer of the fan out package.

The plurality of recesses 322 may be provided in the upper surface 302 of the sealing member 300. The recess 322 may extend in a horizontal direction in the upper surface 302 of the sealing member 300 to at least partially expose an upper sidewall of the through via 310. The buried wirings 412 may be formed in the recesses 322 provided in the upper surface 302 of the sealing member 300. The upper surface of the buried wiring 412 and the upper surface 302 of the sealing member 300 may be coplanar.

The second redistribution wirings 402 may include the buried wirings 412 as first lower redistribution wirings, second upper redistribution wirings 422 and third upper redistribution wirings 432 stacked in three layers. In this case, the buried wiring 412 may correspond to a lowermost redistribution wiring among the upper redistribution wirings, and the third upper redistribution wiring 432 may correspond to an uppermost redistribution wiring among the upper redistribution wirings.

The first upper insulating layer 410 may be provided on the upper surface 302 of the sealing member 300 and the backside surface 202 of the semiconductor chip 200 and may have openings that expose upper surfaces of the buried wirings 412 and the through vias 310. The second upper redistribution wirings 422 may be formed on the first upper insulating layer 410 and at least portions of the second upper redistribution wirings 422 may directly contact the buried wirings 412 and the through vias 310 through the openings of the first upper insulating layer 410.

The second upper insulating layer 420 may be provided on the first upper insulating layer 410 and may have openings that expose the second upper redistribution wirings 422. The third upper redistribution wirings 432 may be formed on the second upper insulating layer 420 and at least portions of the third upper redistribution wirings 432 may directly contact the second upper redistribution wirings 422 through the openings of the second upper insulating layer 420.

Bonding pads (not illustrated) may be provided on the third upper redistribution wirings 432 respectively. A third upper insulating layer 430 may be provided on the second upper insulating layer 420 and may expose at least portions of the second bonding pads. The third upper insulating layer 430 may operate as a passivation layer.

In example embodiments, the external connection members 500 may be disposed on bump pads on the first lower redistribution wirings 112 on the outer surface of the lower redistribution wiring layer 100. For example, the external connection member 500 may include a solder ball. The semiconductor package 12 may be mounted on a module substrate (not illustrated) via the solder balls to form a memory module.

As mentioned above, the buried wiring 412 may be buried in the upper surface 302 of the sealing member 300 to operate as the upper redistribution wiring of one layer. Accordingly, a thickness of the upper redistribution wiring layer 400 may be reduced. Further, since the buried wirings 412 have thermal conductivity higher than EMC, heat dissipation performances may be improved.

Hereinafter, a method of manufacturing the semiconductor package of FIG. 18 will be described.

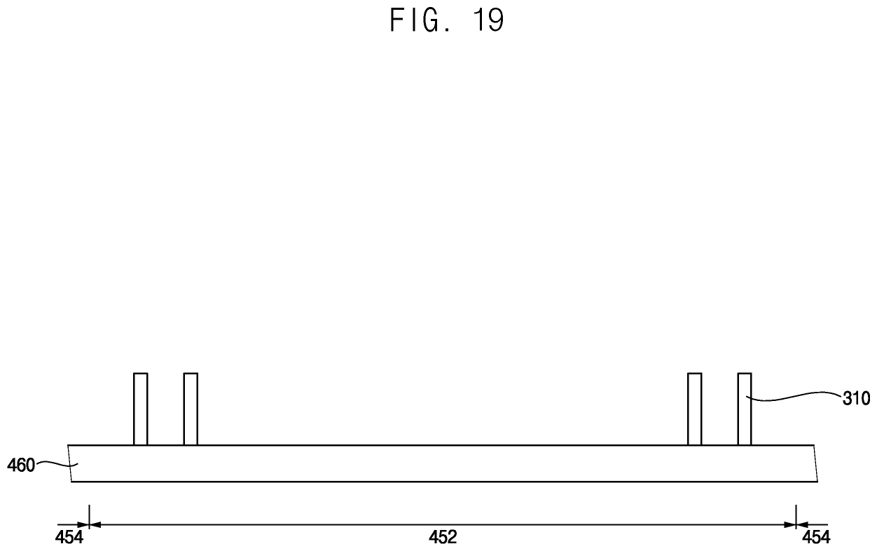

FIGS. 19 to 28 are cross-sectional views illustrating a method of manufacturing a semiconductor package in accordance with example embodiments.

Referring to FIG. 19, a plurality of through vias 310 as conductive structures may be formed on a first carrier substrate 460.

In example embodiments, the first carrier substrate 460 may be used as a base substrate for stacking a plurality of semiconductor chips and forming a molding member covering them. The first carrier substrate 460 may have a shape corresponding to a wafer on which a semiconductor process is performed. The first carrier substrate 460 may include a package region 452 where the semiconductor chip is mounted and a cutting region 454 surrounding the package region 452. As will be described later, a lower redistribution wiring layer and a molding member formed on the first carrier substrate 460 may be cut along the cutting region 454 that divides the plurality of package regions 452 to be individualized.

In particular, for a seed layer and a photoresist layer are formed on the first carrier substrate 460 and an exposure process may be performed on the photoresist layer to form a photoresist pattern having openings for forming the plurality of through vias 310 on a fan out region.

Then, the through vias 310 may be formed by performing an electroplating process to fill the openings of the photoresist pattern with a conductive material. Then, the photoresist pattern may be removed by a strip process, and portions of the seed layer exposed by the through vias 310 may be removed.

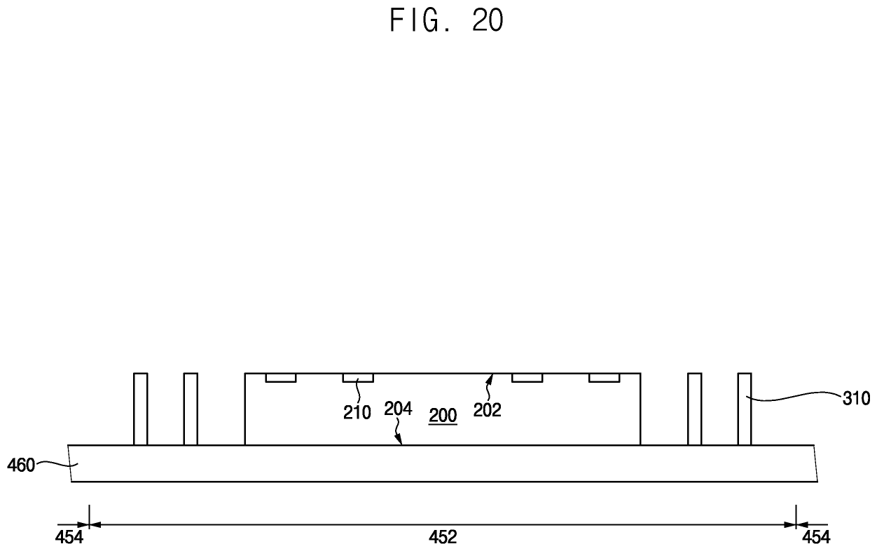

Referring to FIG. 20, at least one semiconductor chip 200 may be disposed on the first carrier substrate 460.

In example embodiments, the semiconductor chip 200 may be disposed in a fan in region of the first carrier substrate 460. The plurality of through vias 310 may be disposed around the semiconductor chip 200. The semiconductor chip 200 may be disposed such that a backside surface 204 opposite to a front surface 202 on which chip pads 210 are formed, that is, an active surface faces the first carrier substrate 460.

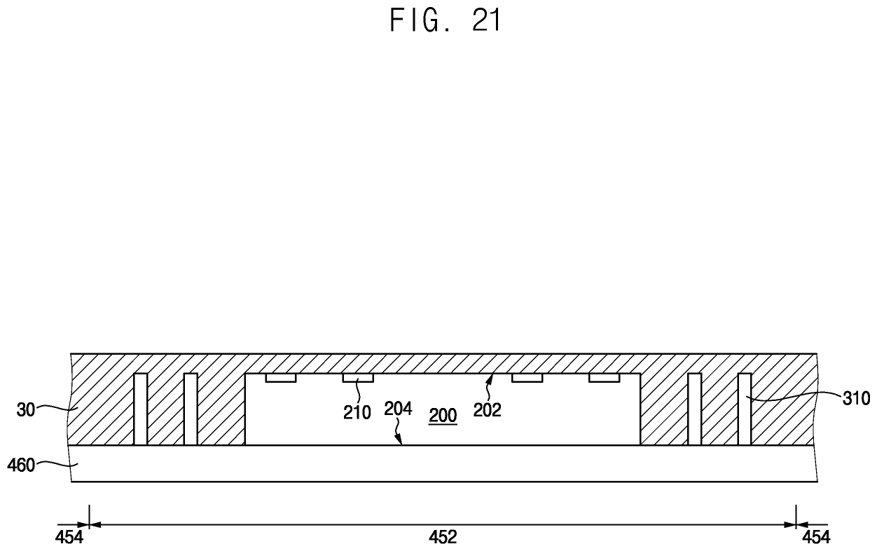

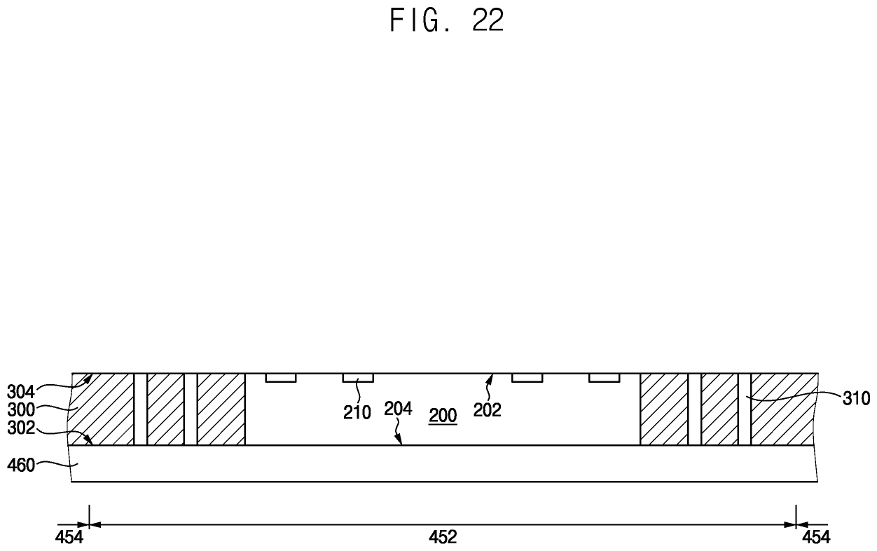

Referring to FIGS. 21 and 22, a sealing material 30 may be formed on the first carrier substrate 460 to cover the semiconductor chip 200 and the plurality of through vias 310, and an upper portion of the sealing material 30 may be partially removed to form an sealing member 300 that exposes the front surface 202 of the semiconductor chip 200 and upper surfaces of the plurality of through vias 310.

The sealing material 30 may be formed to cover the front surface 202 of the semiconductor chip 200 and the upper surfaces of the plurality of through vias 310. For example, the sealing material 30 may include an epoxy molding compound (EMC).

The upper portion of the sealing material 30 may be partially removed by a grinding process. As the upper portion of the sealing material 30 is removed, the chip pads 210 on the front surface 202 of the semiconductor chip 200 and the plurality of through vias 310 may be exposed from a lower surface 304 of the sealing member 300. The sealing member 300 may cover a side surface of the semiconductor chip 200.

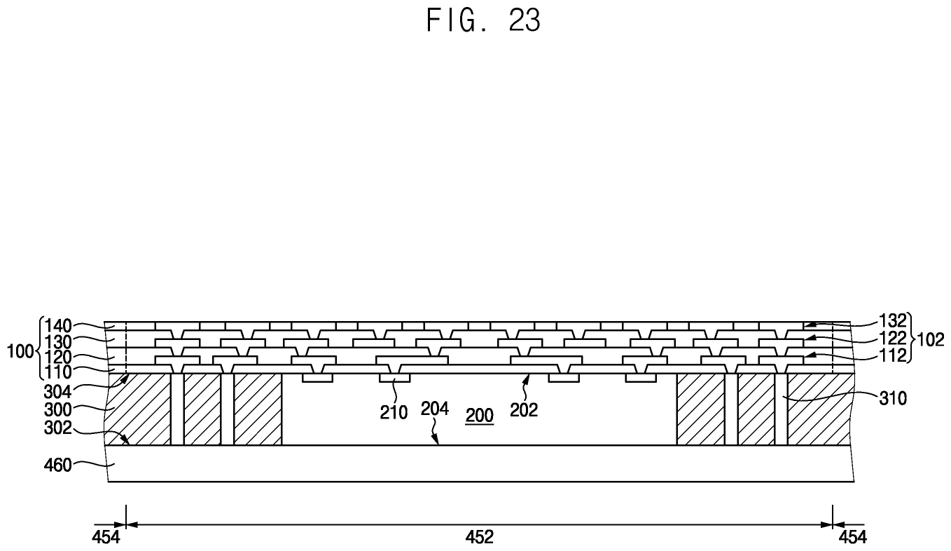

Referring to FIG. 23, a lower redistribution wiring layer 100 having first redistribution wirings 102 may be formed on the lower surface 304 of the sealing member 300 and the front surface 202 of the semiconductor chip 200.

In example embodiments, after a first lower insulating layer 110 is formed on the lower surface 304 of the sealing member 300 and the front surface 202 of the semiconductor chip 200, the first lower insulating layer 110 may be patterned to form openings that expose the through vias 310 and the chip pads 210, respectively. Some of the openings of the patterned first upper insulating layer 410 may expose the through vias 310 and other openings may expose the chip pads 210.

After a seed layer is formed on the through vias 310 and the chip pads 210 and in the openings, the seed layer may be patterned, and an electroplating process may be performed to form the first lower redistribution wirings 112. Accordingly, at least portions of the first lower redistribution wirings 112 may directly contact the through vias 310 and the chip pads 210 through the openings of the first lower insulating layer 110.

Similarly, after the second lower insulating layer 120 is formed on the first lower insulating layer 110, the second lower insulating layer 120 may be patterned to form openings that expose the first lower redistribution wirings 112. Then, the second lower redistribution wirings 122 may be formed on the second lower insulating layer 120 to directly contact the first lower redistribution wirings 112 through the openings of the second lower insulating layer 120.

Then, after the third lower insulating layer 130 is formed on the second lower insulating layer 120, the third lower insulating layer 130 may be patterned to form openings that expose the second lower redistribution wirings 122. Then, the third lower redistribution wirings 132 may be formed on the third lower insulating layer 130 to directly contact the second lower redistribution wirings 122 through the openings of the third lower insulating layer 130.

Then, package pads (not illustrated) may be formed on the third lower redistribution wirings 132, and the fourth lower insulating layer 140 may be formed on the third lower insulating layer 130 and may expose at least a portion of the package pads on the third lower redistribution wirings 132. The fourth lower insulating layer 140 may operate as a passivation layer.

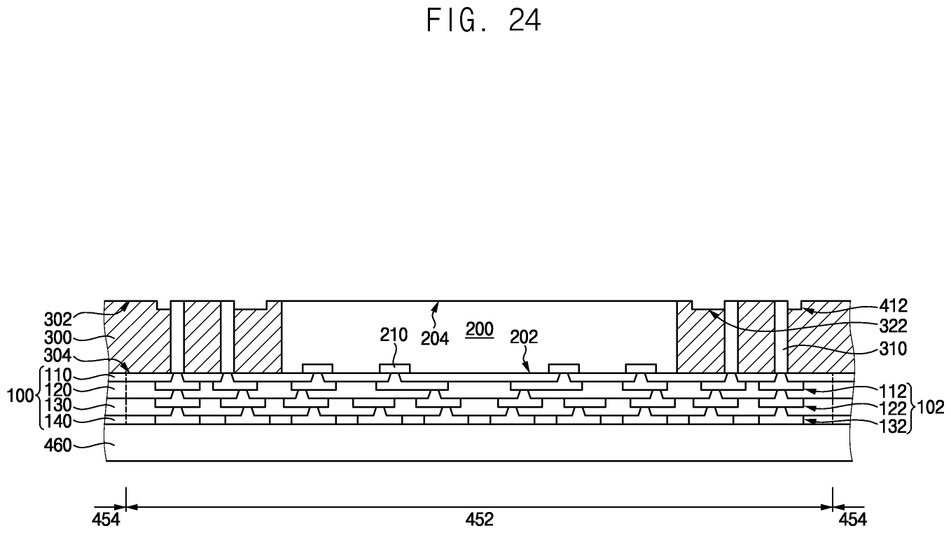

Referring to FIG. 24, a plurality of recesses 322 may be formed in the upper surface 302 of the sealing member 300 to at least partially expose the through vias 310.

In particular, after removing the first carrier substrate 460, the structure of FIG. 23 may be turned over, and the lower redistribution wiring layer 100 may be attached to a second carrier substrate 4502. Then, laser processing may be performed on the upper surface 302 of the sealing member 300 to form the recesses 322 having a predetermined depth. The recesses 322 may be formed by patterning the upper surface of the sealing material 30 using a laser. The recess 322 may expose at least a portion of an upper sidewall of the through via 310.

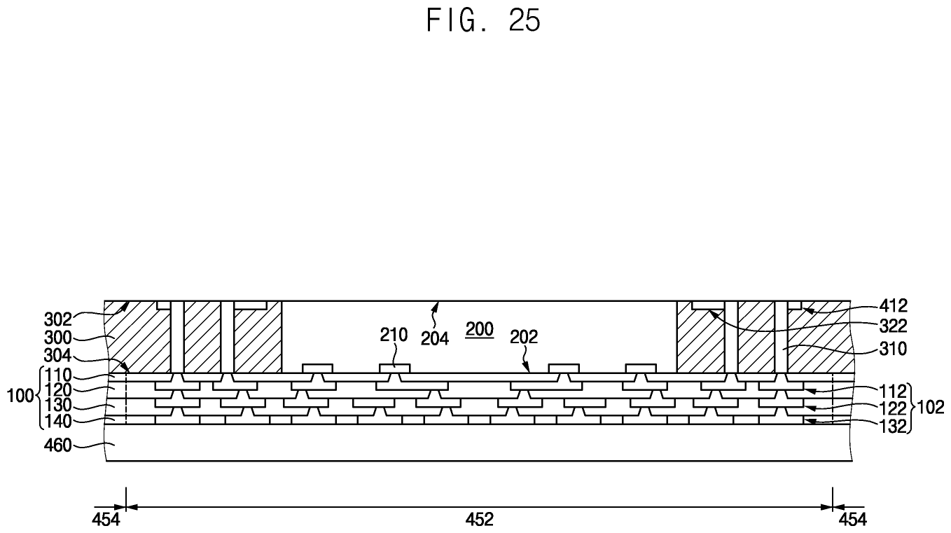

Referring to FIG. 25, processes the same as or similar to the processes described with reference to FIGS. 12 and 13 may be performed to form buried wirings 412 in the recesses 322 provided in the upper surface 302 of the sealing member 300.

The buried wiring 412 may contact at least a portion of the upper sidewall of the through via 310. The buried wiring 412 may be electrically connected to the through via 310. An upper surface of the buried wiring 412 may be coplanar with the upper surface 302 of the sealing member 300.

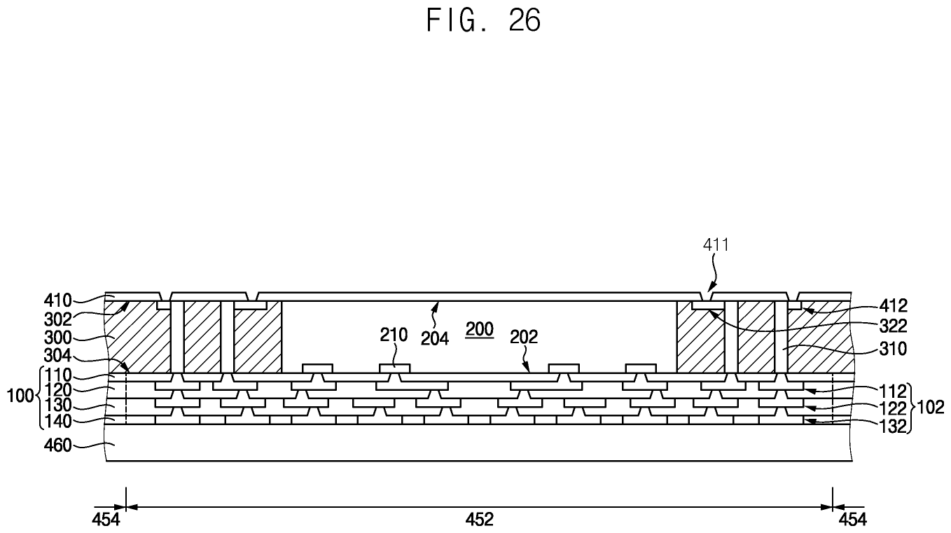

Referring to FIGS. 26 to 28, processes the same as or similar to the processes described with reference to FIGS. 14 to 16 may be performed to form the upper redistribution wiring layer 400 having the second redistribution wirings 402 electrically connected to the buried wires 412 and the through vias 310 on the upper surface 302 of the sealing member 300.

As illustrated in FIG. 26, after the first upper insulating layer 410 is formed on the upper surface 302 of the sealing member 300, the first upper insulating layer 410 may be patterned to form the openings 411 that expose the buried wirings 412 and the through vias 310.

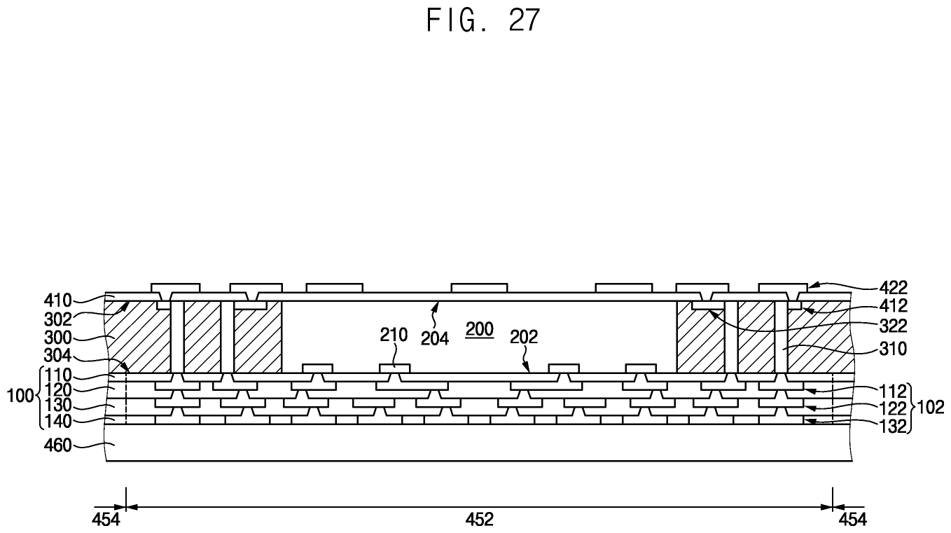

As illustrated in FIG. 27, after a seed layer is formed on portions of the buried wirings 412 and portions of the through vias 310 and in the openings 411, the seed layer may be patterned and an electroplating process may be performed to form the second upper redistribution wirings 422. Accordingly, at least portions of the second upper redistribution wirings 422 may directly contact the buried wirings 412 as first upper redistribution wirings through the openings of the first upper insulating layer 410.

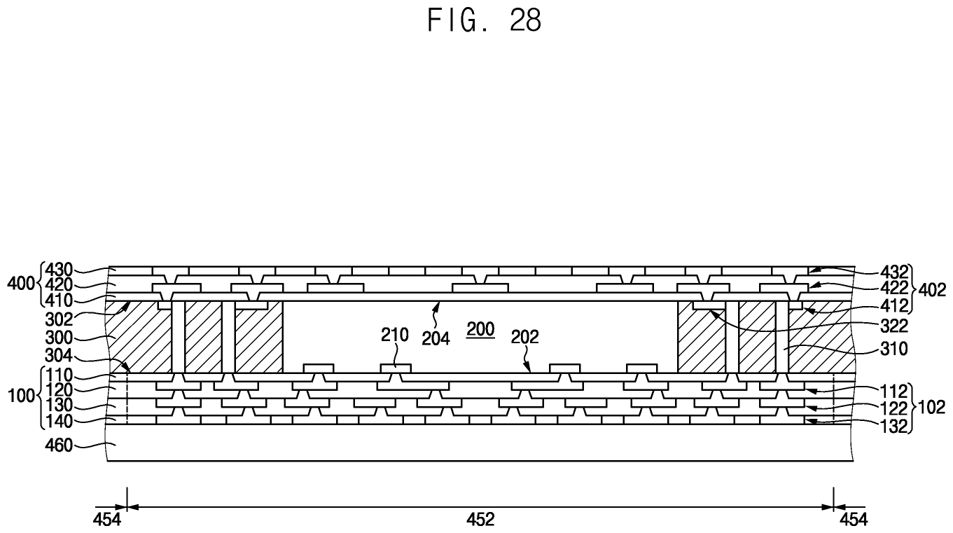

As illustrated in FIG. 28, after the second upper insulating layer 420 is formed on the first upper insulating layer 410, the second upper insulating layer 420 may be patterned to form openings that expose the second upper redistribution wirings 422. Then, the third upper redistribution wirings 432 may be formed on the second upper insulating layer 420 to directly contact the second upper redistribution wirings 422 through the openings of the second upper insulating layer 420.

Thus, the second redistribution wirings 402 may include the buried wiring 412, the second upper redistribution wiring 422 and the third upper redistribution 432 stacked in three layers. In this case, the buried wiring 412 may correspond to a lowermost redistribution wiring among the upper redistribution wirings, and the third upper redistribution wiring 432 may correspond to an uppermost redistribution wiring among the upper redistribution wirings.

Then, bonding pads (not illustrated) may be formed on the third upper redistribution wirings 432 as the uppermost redistribution wirings, respectively, and a third upper insulating layer 430 may be formed on the second upper insulating layer 420 and may expose at least a portion of the bonding pad on the third upper redistribution wiring 432. The third upper insulating layer 430 may operate as a passivation layer.

Then, external connection members 500 (see FIG. 18) may be formed on an outer surface of the lower redistribution wiring layer 100 to be electrically connected to the first redistribution wirings 102.

Then, a sawing process may be performed to individualize the lower redistribution wiring layer 100 to complete the fan out wafer level package 12 of FIG. 18 including the sealing member 300, the lower redistribution wiring layer 100 formed on the lower surface 304 of the sealing member 300 and the upper redistribution wiring layer 400 formed on the upper surface 302 of the sealing member 300.

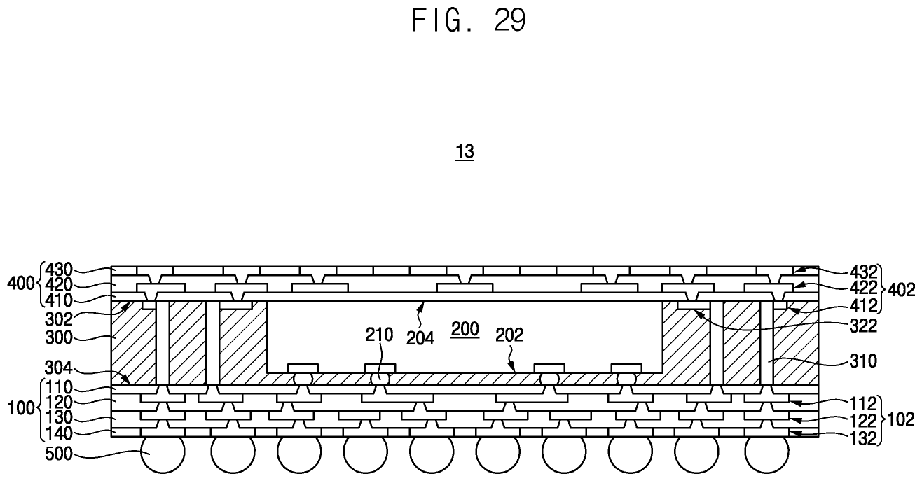

FIG. 29 is a cross-sectional view illustrating a semiconductor package in accordance with example embodiments. The semiconductor package may be substantially the same as the semiconductor package described with reference to FIG. 18 except for a connection relationship between a semiconductor chip and a lower redistribution wiring layer. Thus, same reference numerals may be used to refer to the same or like elements and any further repetitive explanation concerning the above elements will be omitted.

Referring to FIG. 29, a semiconductor package 13 may include the lower redistribution wiring layer 100, the semiconductor chip 200 disposed on the lower redistribution wiring layer 100, the sealing member 300 covering at least one side surface of the semiconductor chips 200 on the lower redistribution wiring layer 100, and the upper redistribution wiring layer 400 disposed on the sealing member 300. In addition, the semiconductor package 12 may further include the external connection members 500 disposed on an outer surface of the lower redistribution wiring layer 100.

In example embodiments, the semiconductor chip 200 may have the plurality of chip pads 210 on the front surface 202, that is, an active surface thereof. The semiconductor chip 200 may be accommodated in the sealing member 300 such that the front surface 202 on which the chip pads 210 are formed faces the lower redistribution wiring layer 100. The sealing member 300 may cover the front surface 202 and the side surface of the semiconductor chip 200. The backside surface 202 opposite to the front surface 202 of the semiconductor chip 200 may be exposed from the upper surface 302 of the sealing member 300.

The semiconductor chip 200 may be mounted on the lower redistribution wiring layer 100 via the conductive bumps 220. The conductive bump 220 may be disposed between the first lower redistribution wiring 112 of the lower redistribution wiring layer 100 and the chip pad 210 of the semiconductor chip 200 to electrically connect each other.

The sealing member 300 may cover at least a portion of the semiconductor chip 200 on the upper surface of the lower redistribution wiring layer 100. The sealing member 300 a second sealing portion covering the upper surface of the lower redistribution wiring layer 100 around the semiconductor chip 200 and the third sealing portion covering the front surface 202 of the semiconductor chip 200.

In example embodiments, the upper redistribution wiring layer 400 may be disposed on the upper surface 302 of the sealing member 300 and the backside surface 202 of the semiconductor chip 200 and may include second redistribution wires 402 electrically connected to the through vias 310. The second redistribution wirings 402 may include the buried wiring 412 buried in the upper surface 302 of the sealing member 300 and an upper redistribution wiring stacked in at least one layer on the buried wiring 412. The second redistribution wirings 402 may be provided on the sealing member 300 to operate as backside redistribution wirings. Accordingly, the upper redistribution wiring layer 400 may be a backside redistribution wiring layer of a fan out package.

Hereinafter, a method of manufacturing the semiconductor package of FIG. 29 will be described.

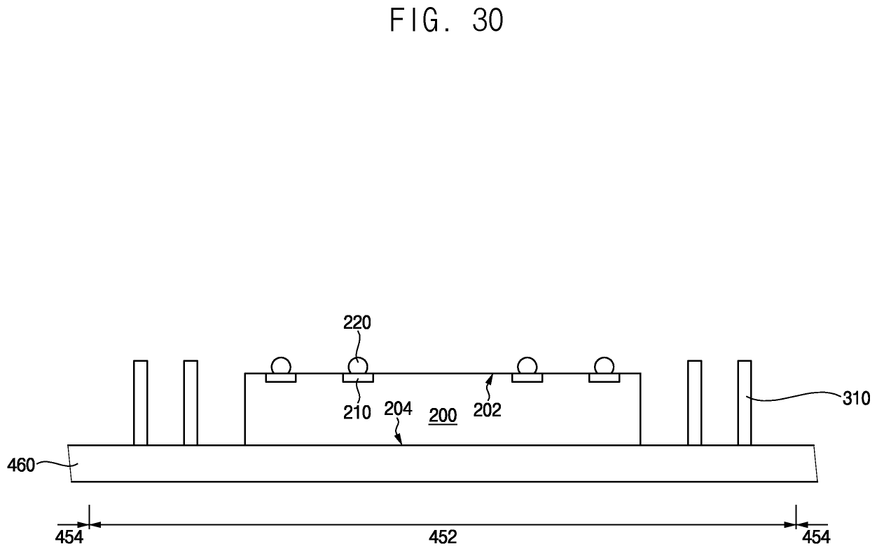

FIGS. 30 to 33 are cross-sectional views illustrating a method of manufacturing a semiconductor package in accordance with example embodiments.

Referring to FIG. 30, first, processes the same as or similar to the processes described with reference to FIG. 19 may be performed to form a plurality of through vias 310 as conductive structures on a first carrier substrate 460 and dispose a semiconductor chip 200 on the first carrier substrate 460.

example embodiments, conductive bumps 220 may be formed on chip pads 210 of the semiconductor chip 200, and the semiconductor chip 200 may be disposed such that a backside surface 204 opposite to the front surface 202 on which the chip pads 210 are formed, that is, an active surface faces the first carrier substrate 460. The semiconductor chip 200 may be disposed in a fan in a region of the first carrier substrate 460. The plurality of through vias 310 may be disposed around the semiconductor chip 200.

The conductive bump 220 may include a pillar bump formed on the chip pad 210 of the semiconductor chip 200 and a solder bump formed on the pillar bump. Alternatively, the conductive bump 220 may include a solder bump formed on the chip pad 210 of the semiconductor chip 200.

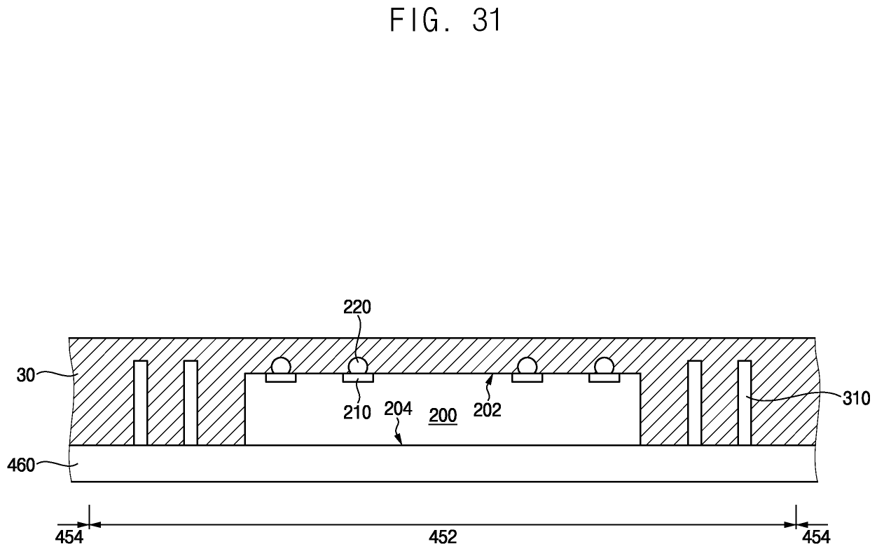

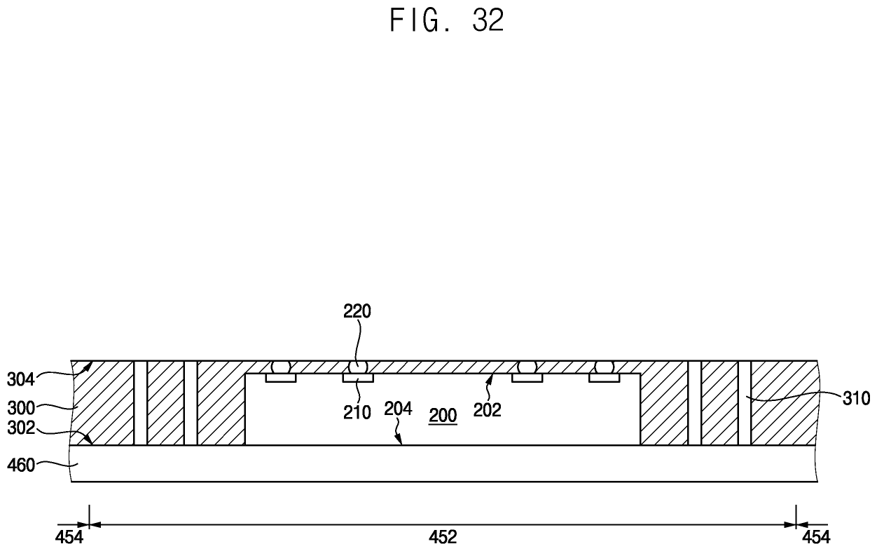

Referring to FIGS. 31 and 32, the sealing material 30 may be formed on the first carrier substrate 460 to cover the semiconductor chip 200 and the plurality of through vias 310, and an upper portion of the sealing material 30 may be partially removed to form the sealing member 300 that exposes upper surfaces of the conductive bumps 220 on the front surface 202 of the semiconductor chip 200 and the plurality of through vias 310.

The sealing material 30 may be formed to cover the front surface 202 of the semiconductor chip 200 and upper surfaces of the plurality of through vias 310. For example, the sealing material 30 may include an epoxy molding compound (EMC).

The upper portion of the sealing material 30 may be partially removed by a grinding process. As the upper portion of the sealing material 30 is removed, the conductive bumps 220 on the front surface 202 of the semiconductor chip 200 and the plurality of through vias 310 may be exposed from a lower surface 304 of the sealing member 300. The sealing member 300 may include a second sealing portion covering the side surface of the semiconductor chip 200 and a third sealing portion covering the front surface 202 of the semiconductor chip 200. Upper surfaces of the conductive bumps 220 on the front surface 202 of the semiconductor chip 200 may be exposed by the third sealing portion of the sealing member 300.

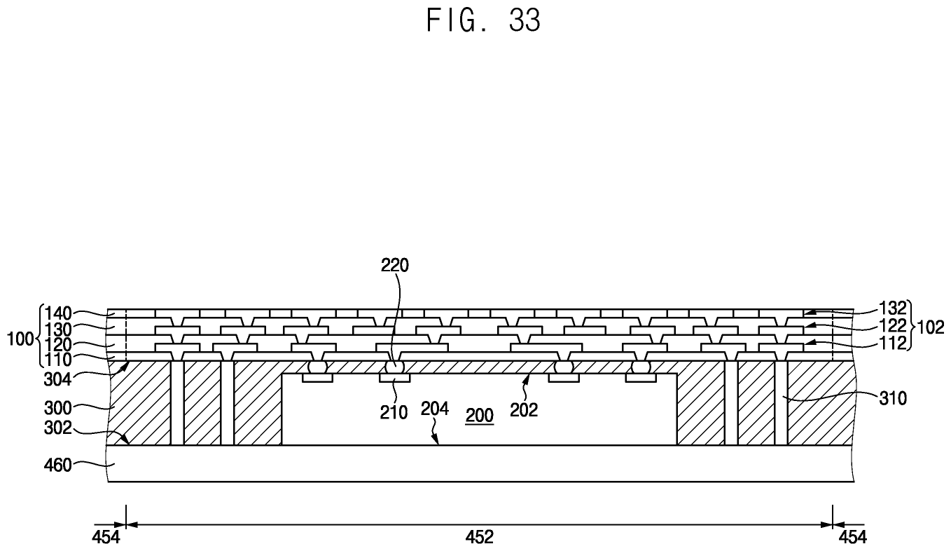

Referring to FIG. 33, processes the same as or similar to the processes described with reference to FIG. 23 may be performed to form a lower redistribution wiring layer 100 having first redistribution wires 102 on the lower surface 304 of the sealing member 300.

In example embodiments, after forming the first lower insulating layer 110 on the lower surface 304 of the sealing member 300, the first lower insulating layer 110 may be patterned to form openings that expose the conductive bumps 220 and the through vias 310. Some of the openings of the patterned first upper insulating layer 410 may expose the through vias 310 and other openings may expose the conductive bumps 220.

After forming a seed layer on the through vias 310 and the conductive bumps 220 and in the openings, the seed layer may be patterned and an electroplating process may be performed to form first lower redistribution wirings 112. Accordingly, at least portions of the first lower redistribution wirings 112 may directly contact the through vias 310 and the conductive bumps 220 through the openings of the first lower insulating layer 110.

Similarly, after the second lower insulating layer 120 is formed on the first lower insulating layer 110, the second lower insulating layer 120 may be patterned to form openings that expose the first lower redistribution wirings 112. Then, the second lower redistribution wirings 122 may be formed on the second lower insulating layer 120 to directly contact the first lower redistribution wirings 112 through the openings of the second lower insulating layer 120.

Then, after forming the third lower insulating layer 130 on the second lower insulating layer 120, the third lower insulating layer 130 may be patterned to form openings that expose the second lower redistribution wirings 122. Then, the third lower redistribution wirings 132 may be formed on the third lower insulating layer 130 to directly contact the second lower redistribution wirings 122 through the openings of the second lower insulating layer 120.

Then, package pads (not illustrated) may be formed on the third lower redistribution wirings 132, and the fourth lower insulating layer 140 may be formed on the third lower redistribution wiring layer 130 to expose at least a portion of the package pad on the third lower redistribution wiring 132. The fourth lower insulating layer 140 may operate as a passivation layer.

Then, processes the same as or similar to the processes described with reference to FIGS. 24 to 28 may be performed to an upper redistribution wiring layer 400 having buried wirings 412 in the upper surface 302 of the sealing member 300. The second redistribution wirings 402 electrically connect the through vias 310 on the upper surface 302 of the sealing member 300 and form external connection members on an outer surface of the lower redistribution wiring layer 100 to be electrically connected to the first redistribution wirings 102 to thereby complete the manufacture of the fan out wafer level package 13 of FIG. 29.

The semiconductor package may include semiconductor devices, such as logic devices or memory devices. The semiconductor package may include logic devices, such as CPUs, MPUs, APs, and the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments as defined in the claims.

What is claimed is:

1. A semiconductor package, comprising:
a lower redistribution wiring layer including first redistribution wirings;
a semiconductor chip on the lower redistribution wiring layer and electrically connected to the first redistribution wirings;
a sealing member on the semiconductor chip on the lower redistribution wiring layer;
a plurality of through vias penetrating the sealing member and electrically connected to the first redistribution wirings;
an upper redistribution wiring layer on the sealing member and having second redistribution wirings electrically connected to the plurality of through vias, wherein the second redistribution wirings includes buried wirings that are buried in a plurality of recesses formed in an upper surface of the sealing member and electrically connected to the plurality of through vias; and
upper redistribution wirings provided in at least one upper insulating layer on the sealing member and electrically connected to the buried wirings.

2. The semiconductor package of claim 1, wherein at least one of the buried wirings partially contact the plurality of through vias.

3. The semiconductor package of claim 2, wherein at least one of the buried wirings contact an upper sidewall of the plurality of through vias.

4. The semiconductor package of claim 1, wherein an upper surface of the buried wirings and the upper surface of the sealing member are coplanar.

5. The semiconductor package of claim 1, wherein a thickness of a buried wiring of the plurality of buried wirings is within a range of 3 μm to 20 μm, including endpoints.

6. The semiconductor package of claim 1, wherein the sealing member includes a first sealing portion covering an upper surface of the semiconductor chip and a second sealing portion covering an upper surface of the lower redistribution wiring layer around the semiconductor chip.

7. The semiconductor package of claim 6, wherein the buried wirings are provided on an upper surface of the first sealing portion and an upper surface of the second sealing portion.

8. The semiconductor package of claim 1, wherein the semiconductor chip is mounted on the lower redistribution wiring layer via conductive bumps.

9. The semiconductor package of claim 1, wherein the sealing member exposes an upper surface of the semiconductor chip.

10. The semiconductor package of claim 1, further comprising a second package disposed on the upper redistribution wiring layer, wherein the second package includes a package substrate and at least one second semiconductor chip on the package substrate.

11. A semiconductor package, comprising:
a lower redistribution wiring layer including first redistribution wirings;
a semiconductor chip on the lower redistribution wiring layer, wherein the semiconductor chip includes chip pads formed on a first surface of the semiconductor chip, and wherein the first surface of the semiconductor chip faces the lower redistribution wiring layer;
a sealing member on the semiconductor chip on the lower redistribution wiring layer;
a plurality of through vias penetrating the sealing member and electrically connected to the first redistribution wirings; and
an upper redistribution wiring layer disposed on the sealing member, wherein the upper redistribution wiring layer includes:
buried wirings formed in recesses of an upper surface of the sealing member and electrically connected to the plurality of through vias;
at least one upper insulating layer on the upper surface of the sealing member; and
upper redistribution wirings provided in the at least one upper insulating layer and electrically connected to the buried wirings.

12. The semiconductor package of claim 11, wherein at least one of the buried wirings partially contact the plurality of through vias.

13. The semiconductor package of claim 12, wherein at least one of the buried wirings contact an upper sidewall of the plurality of through vias.

14. The semiconductor package of claim 11, wherein an upper surface of the buried wirings and the upper surface of the sealing member are coplanar.

15. The semiconductor package according to claim 11, wherein a thickness of a buried wiring of the buried wirings is within a range of 3 μm to 20 μm, including endpoints.

16. The semiconductor package of claim 11, wherein the sealing member includes a first sealing portion covering an upper surface of the semiconductor chip and a second sealing portion covering an upper surface of the lower redistribution wiring layer around the semiconductor chip.

17. The semiconductor package of claim 16, wherein the buried wirings are provided on an upper surface of the first sealing portion and an upper surface of the second sealing portion.

18. The semiconductor package of claim 11, wherein the semiconductor chip is mounted on the lower redistribution wiring layer via conductive bumps.

19. The semiconductor package of claim 11, further comprising a second package on the upper redistribution wiring layer, wherein the second package includes a package substrate and at least one second semiconductor chip on the package substrate.

20. A semiconductor package, comprising:
a lower redistribution wiring layer including first redistribution wirings;
a semiconductor chip on the lower redistribution wiring layer, wherein the semiconductor chip includes chip pads formed on a first surface of the semiconductor chip, and wherein the first surface of the semiconductor chip faces the lower redistribution wiring layer;
a sealing member on an outer surface of the semiconductor chip on the lower redistribution wiring layer and exposing a second surface of the semiconductor chip opposite to the first surface;
a plurality of through vias penetrating the sealing member and electrically connected to the first redistribution wirings; and
upper redistribution wiring layer on the sealing member and having second redistribution wirings electrically connected to the plurality of through vias,
wherein the second redistribution wirings includes:
buried wirings that are buried in a plurality of recesses formed in an upper surface of the sealing member and electrically connected to the plurality of through vias; and
an upper redistribution wiring provided in at least one upper insulating layer that is on the sealing member and electrically connected to the buried wirings.
